(19) United States
(12) Patent Application Publication
(10) Pub. No.: US 2026/0239611 A1
(43) Pub. Date: Aug. 13, 2026

(54) SEMICONDUCTOR DEVICE

(71) Applicant: Samsung Electronics Co., Ltd., Suwon-si (KR)

(72) Inventors: Dong Gun Kim, Suwon-si (KR); Chun Hyung Chung, Suwon-si (KR)

(73) Assignee: Samsung Electronics Co., Ltd., Suwon-si (KR)

(21) Appl. No.: 19/369,896

(22) Filed: Oct. 27, 2025

(30) Foreign Application Priority Data
Feb. 11, 2025 (KR) 10-2025-0017176

(51) Int. Cl. H10B 12/00; H10D 30/01; H10D 64/66; H10D 64/68

(52) U.S. Cl. CPC H10B 12/50; H10B 12/315; H10B 12/34; H10D 64/667; H10D 64/685; H10D 64/691; H10D 30/027

(57) ABSTRACT

Provided is A semiconductor device. The semiconductor device includes a substrate including a first region and a second region, a first gate structure in the first region, including a first gate insulating layer that includes a first high-k film and a first conductivity-type metal oxide film of a first conductivity type, and a first gate electrode layer on the first gate insulating layer; and a second gate structure in the second region, including a second gate insulating layer that includes a second high-k film, the first conductivity-type metal oxide film, and a second conductivity-type metal oxide film of a second conductivity-type different from the first conductivity type, and a second gate electrode layer on the second gate insulating layer, wherein the second gate electrode layer includes a barrier film between the first conductivity-type metal oxide film and the second high-k film, and the barrier film includes a semimetal material.

### CROSS-REFERENCE TO RELATED APPLICATIONS

This present application claims priority to and the benefit under 35 U.S.C. § 119(a)-(d) of Korean Patent Application No. 10-2025-0017176, filed on Feb. 11, 2025, in the Korean Intellectual Property Office, the entire disclosure of which is incorporated herein by reference.

### FIELD

The present disclosure relates to a semiconductor device.

### BACKGROUND

A semiconductor device may include N-type metal-oxide semiconductor (NMOS) transistors and P-type metal-oxide semiconductor (PMOS) transistors. Through a manufacturing process of the semiconductor device, NMOS transistors and PMOS transistors having targeted characteristics must be respectively formed on a substrate. However, forming a semiconductor device that satisfies the target electrical characteristics of NMOS transistors and PMOS transistors.

### SUMMARY

An objective of the present disclosure is to provide a semiconductor device including N-type metal-oxide semiconductor (NMOS) transistors and P-type metal-oxide semiconductor (PMOS) transistors with target electrical characteristics.

The objectives of the present disclosure are not limited to those mentioned above, and other objectives not explicitly stated will be clearly understood by those skilled in the art based on the following description.

A semiconductor device according to some embodiments of the present disclosure includes a substrate including a first region and a second region, a first gate structure in the first region, including a first gate insulating layer that includes a first high-k film and a first conductivity-type metal oxide film of a first conductivity type, and a first gate electrode layer on the first gate insulating layer; and a second gate structure in the second region, including a second gate insulating layer that includes a second high-k film, the first conductivity-type metal oxide film, and a second conductivity-type metal oxide film of a second conductivity-type different from the first conductivity type, and a second gate electrode layer on the second gate insulating layer, wherein the second gate electrode layer includes a barrier film between the first conductivity-type metal oxide film and the second high-k film, and the barrier film includes a semimetal material.

A semiconductor device according to some embodiments of the present disclosure includes a substrate including a first region and a second region, a first transistor in the first region, including a first gate insulating layer and a first gate electrode layer, and a second transistor in the second region, including a second gate insulating layer and a second gate electrode layer, wherein the first gate insulating layer includes a first high-k film on the substrate and a first metal oxide film including a first conductivity-type metal material, the second gate insulating layer includes a second high-k film on the substrate, the first metal oxide film, and a second metal oxide film including a second conductivity-type metal material different from the first conductivity-type metal material, the second gate electrode layer includes a barrier film between the first metal oxide film and the second high-k film, and the second high-k film does not include the first conductivity-type metal material.

A semiconductor device according to some embodiments of the present disclosure includes a substrate including a cell array region, a first peripheral region, and a second peripheral region, a cell structure in the cell array region, including bitlines extending in a first direction, wordlines extending in a second direction that intersects the first direction, and a capacitor on the bitlines, a first transistor in the first peripheral region, including a first gate insulating layer that includes a first high-k film and a first conductivity-type metal oxide film of a first conductivity type, and a first gate electrode layer on the first gate insulating layer, and a second transistor in the second peripheral region, including a second gate insulating layer that includes a second high-k film, the first conductivity-type metal oxide film, and a second conductivity-type metal oxide film of a second conductivity type different from the first conductivity type, and a second gate electrode layer on the second gate insulating layer, wherein the second gate electrode layer includes a barrier film between the first conductivity-type metal oxide film and the second high-k film, and the barrier film includes a semimetal material.

A method for manufacturing a semiconductor device according to some embodiments includes providing a substrate including a first region and a second region, providing a first gate structure in the first region, including a first gate insulating layer that includes a first high-k film and a first conductivity-type metal oxide film of a first conductivity type, and a first gate electrode layer on the first gate insulating layer; and providing a second gate structure in the second region, including a second gate insulating layer that includes a second high-k film, the first conductivity-type metal oxide film, and a second conductivity-type metal oxide film of a second conductivity-type different from the first conductivity type, and a second gate electrode layer on the second gate insulating layer, wherein the second gate electrode layer includes a barrier film between the first conductivity-type metal oxide film and the second high-k film, and the barrier film includes a semimetal material.

A method for manufacturing a semiconductor device according to some embodiments includes providing a substrate including a first region and a second region, providing a first transistor in the first region, including a first gate insulating layer and a first gate electrode layer, and providing a second transistor in the second region, including a second gate insulating layer and a second gate electrode layer, wherein the first gate insulating layer includes a first high-k film on the substrate and a first metal oxide film including a first conductivity-type metal material, the second gate insulating layer includes a second high-k film on the substrate, the first metal oxide film, and a second metal oxide film including a second conductivity-type metal material different from the first conductivity-type metal material, the second gate electrode layer includes a barrier film between the first metal oxide film and the second high-k film, and the second high-k film does not include the first conductivity-type metal material.

A method for manufacturing a semiconductor device according to some embodiments includes providing a substrate including a cell array region, a first peripheral region, and a second peripheral region, providing a cell structure in the cell array region, including bitlines extending in a first direction, wordlines extending in a second direction that intersects the first direction, and a capacitor on the bitlines, providing a first transistor in the first peripheral region, including a first gate insulating layer that includes a first high-k film and a first conductivity-type metal oxide film of a first conductivity type, and a first gate electrode layer on the first gate insulating layer, and providing a second transistor in the second peripheral region, including a second gate insulating layer that includes a second high-k film, the first conductivity-type metal oxide film, and a second conductivity-type metal oxide film of a second conductivity type different from the first conductivity type, and a second gate electrode layer on the second gate insulating layer, wherein the second gate electrode layer includes a barrier film between the first conductivity-type metal oxide film and the second high-k film, and the barrier film includes a semimetal material.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a diagram for explaining a semiconductor device according to some embodiments;

FIG. 2 is a diagram for explaining a semiconductor device according to some embodiments;

FIG. 3 is a schematic layout diagram illustrating a semiconductor device according to some embodiments;

FIG. 4 is an enlarged schematic layout diagram of region R3 in FIG. 3;

FIG. 5 is a cross-sectional view taken along line A-A of FIG. 4;

FIG. 6 is a cross-sectional view taken along line B-B of FIG. 4;

FIG. 7 is a layout diagram illustrating a semiconductor device according to some embodiments;

FIG. 8 is a perspective view illustrating the semiconductor device according to some embodiments;

FIG. 9 is a cross-sectional view taken along lines C-C and D-D of FIG. 7;

FIG. 10 is a layout diagram illustrating a semiconductor device according to some embodiments;

FIG. 11 is a perspective view illustrating the semiconductor device according to some embodiments;

FIG. 12 is a diagram illustrating a semiconductor device according to some embodiments;

FIGS. 13 through 17 are intermediate-step diagrams illustrating a method for fabricating a semiconductor device according to some embodiments;

FIG. 18 is an intermediate-step diagram illustrating a method for fabricating a semiconductor device according to some embodiments;

FIGS. 19 through 23 are intermediate-step diagrams illustrating a method for fabricating a semiconductor device according to some embodiments;

FIG. 24 is an intermediate-step diagram illustrating a method for fabricating a semiconductor device according to some embodiments.

### DETAILED DESCRIPTION

Embodiments of the present disclosure will hereinafter be described with reference to the accompanying drawings.

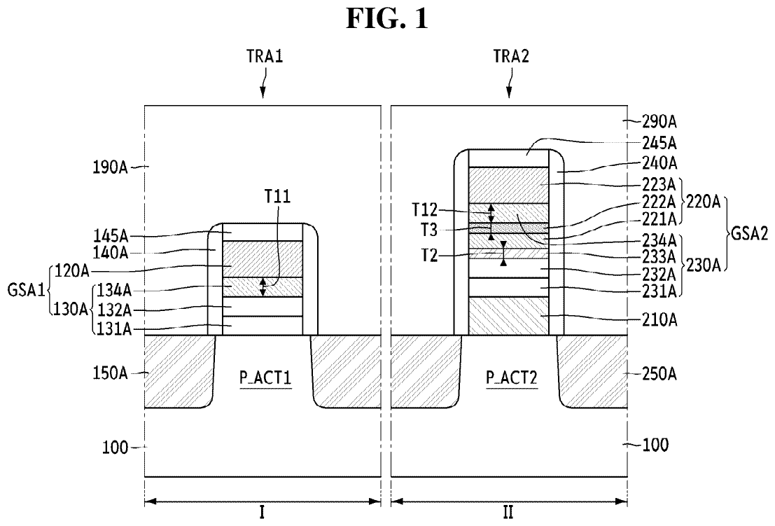

FIG. 1 is a diagram for explaining a semiconductor device according to some embodiments.

Referring to FIG. 1, the semiconductor device according to some embodiments may include a substrate 100, a first transistor TRA1, and a second transistor TRA2.

The substrate 100 may include a first region I and a second region II. The first and second regions I and II may be spaced apart from each other or may be connected to each other.

The substrate 100 may be a silicon substrate or a silicon-on-insulator (SOI) substrate. Alternatively, the substrate 100 may include silicon germanium, silicon germanium-on-insulator (SGOI), indium antimonide, a lead telluride compound, indium arsenide, indium phosphide, gallium arsenide, or gallium antimonide, but is not limited thereto.

The first transistor TRA1 may include a first gate structure GSA1 and first source/drain regions 150A. The second transistor TRA2 may include a second gate structure GSA2 and second source/drain regions 250A.

The first gate structure GSA1 may include a first gate insulating layer 130A and a first gate electrode layer 120A. The second gate structure GSA2 may include a second gate insulating layer 230A and a second gate electrode layer 220A.

The first gate insulating layer 130A, the first gate electrode layer 120A, and the first source/drain regions 150A may be arranged in the first region I of the substrate 100. A silicon germanium film 210A, the second gate insulating layer 230A, the second gate electrode layer 220A, and the second source/drain regions 250A may be arranged in the second region II of the substrate 100.

Although not illustrated, an element isolation film (not illustrated) may be arranged in the substrate 100. The substrate 100 may include an active region defined by the element isolation film. For example, the element isolation film may define a first peripheral active region P_ACT1 and a second peripheral active region P_ACT2.

The first peripheral active region P_ACT1 included in the first region I may be, for example, a region where an N-type metal-oxide semiconductor (NMOS) transistor is formed. The second peripheral active region P_ACT2 included in the second region II may be a region where a P-type metal-oxide semiconductor (PMOS) transistor is formed.

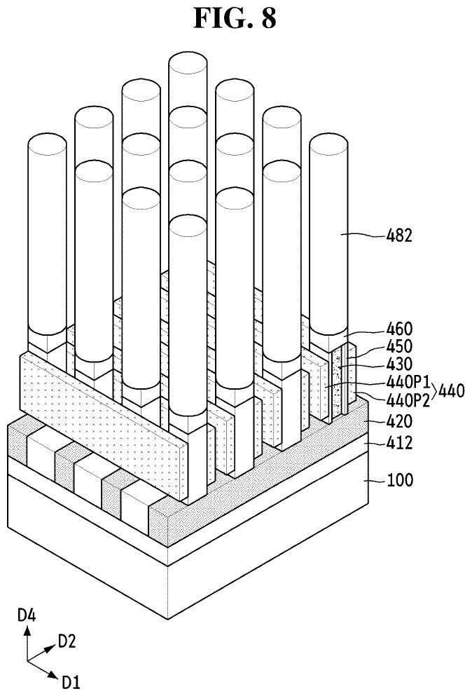

The element isolation film may be formed as a shallow trench isolation (STI) structure. The element isolation film may extend in the thickness direction of the substrate 100 (e.g., a fourth direction D4 of FIG. 8).

The element isolation film may include at least one of silicon oxide, silicon nitride, silicon oxynitride, or a combination thereof.

The silicon germanium film 210A may be arranged on the second peripheral active region P_ACT2. The silicon germanium film 210A may be arranged on the top surface of the substrate 100. The silicon germanium film 210A may be in contact with the substrate 100.

The silicon germanium film 210A may include silicon germanium. For example, the silicon germanium film 210A may include a monocrystalline silicon germanium film.

In one example, the silicon germanium film 210A may include doped p-type and/or n-type impurities. In another example, the silicon germanium film 210A may be formed as an undoped silicon germanium film. Here, “undoped” does not mean that no impurities are included, but rather that no impurities are intentionally doped. That is, an undoped silicon germanium film may or may not contain impurities.

The first gate insulating layer 130A may include a first interfacial layer 131A, a first high-k insulating film 132A, and a (1_1)-th conductivity-type metal oxide film 134A that are sequentially arranged on the substrate 100. The first interfacial layer 131A may be arranged between the substrate 100 and the first high-k insulating film 132A.

The second gate insulating layer 230A may include a second interfacial layer 231A, a second high-k insulating film 232A, a first conductive-type metal oxide film 234A, and a (1_2)-th conductivity-type metal oxide film 233A that are sequentially arranged on the substrate 100.

The second interfacial layer 231A may be arranged between the silicon germanium film 210A and the second high-k insulating film 232A. The second interfacial layer 231A may be in contact with the silicon germanium film 210A. For example, the second interfacial layer 231A may be in direct contact with the top surface of the silicon germanium film 210A. The first and second interfacial layers 131A and 231A may each include, for example, a silicon oxide film.

The first and second high-k insulating films 132A and 232A may each include a high-k material with a higher dielectric constant than silicon oxide. The high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include negative capacitance field-effect transistors (NCFETs) using a negative capacitor. For example, the first and second high-k insulating films 132A and 232A may each include a ferroelectric material film having ferroelectric properties and a paraelectric material film having paraelectric properties.

The ferroelectric material film may have negative capacitance, and the paraelectric material film may have positive capacitance. When two capacitors with positive capacitance are connected in series, the combined capacitance of the two capacitors may be smaller than the individual capacitances of the two capacitors. Conversely, when at least one of the two capacitors has negative capacitance, the combined capacitance of the two capacitors may be positive and greater than the absolute values of the individual capacitances of the two capacitors. When a ferroelectric material film with negative capacitance and a paraelectric material film with positive capacitance are connected in series, the combined capacitance of the two material films may increase. By utilizing this increase in total capacitance, a transistor including the ferroelectric material film may have a subthreshold swing of less than 60 m V/decade at room temperature.

The ferroelectric material film may include at least one of hafnium oxide, hafnium zirconium oxide, barium strontium titanium oxide, barium titanium oxide, or lead zirconium titanium oxide. Here, the hafnium zirconium oxide may be a material in which zirconium (Zr) is doped into hafnium oxide. Alternatively, the hafnium zirconium oxide may be a compound of hafnium (Hf), Zr, and oxygen (O).

The ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material film may vary depending on the type of ferroelectric material contained in the ferroelectric material film.

When the ferroelectric material film includes hafnium oxide, the dopant contained in the ferroelectric material film may include at least one of Gd, Si, Zr, Al, or Y.

When the dopant is Al, the ferroelectric material film may include 3 to 8 atomic percent (at %) of aluminum. Here, the dopant ratio may be defined as the ratio of Al to the sum of Hf and Al.

When the dopant is Si, the ferroelectric material film may include 2 to 10 at % of Si.

When the dopant is Y, the ferroelectric material film may include 2 to 10 at % of Y. When the dopant is Gd, the ferroelectric material film may include 1 to 7 at % of Gd. When the dopant is Zr, the ferroelectric material film may include 50 to 80 at % of Zr.

The paraelectric material film may have paraelectric properties. The paraelectric material film may include at least one of silicon oxide and a metal oxide having a high dielectric constant. The metal oxide contained in the paraelectric material film may include at least one of hafnium oxide, zirconium oxide, or aluminum oxide, but is not limited thereto.

The ferroelectric material film and the paraelectric material film may contain the same material. The ferroelectric material film has ferroelectric properties, whereas the paraelectric material film may not have ferroelectric properties. For example, when both the ferroelectric material film and the paraelectric material film contain hafnium oxide, the crystal structure of the hafnium oxide in the ferroelectric material film is different from that in the paraelectric material film.

The ferroelectric material film may have a thickness that exhibits ferroelectric properties. The thickness of the ferroelectric material film may be, for example, 0.5 to 10 nm, but is not limited thereto. Since the critical thickness at which ferroelectric properties appear varies from ferroelectric material to ferroelectric material, the thickness of the ferroelectric material film may vary depending on its ferroelectric material.

In one example, the first and second gate insulating layers 130A and 230A may each include a single ferroelectric material film. In another example, the first and second gate insulating layers 130A and 230A may each include multiple ferroelectric material films spaced apart from each other. The first and second gate insulating layers 130A and 230A may each include a stacked film structure in which multiple ferroelectric material films and multiple paraelectric material films are alternately stacked.

The (1_1)-th conductivity-type metal oxide film 134A may include an oxide of an N-type dipole element. The (1_1)-th conductivity-type metal oxide film 134A may have a smaller oxygen content per unit volume than silicon oxide. For example, the N-type dipole element may include La, but is not limited thereto. In this case, the (1_1)-th conductivity-type metal oxide film 134A may include lanthanum oxide (LaO). The (1_1)-th conductivity-type metal oxide film 134A may diffuse the N-type dipole element into the first gate insulating layer 130A.

Through a heat treatment process, the metal material contained in the (1_1)-th conductivity-type metal oxide film 134A, i.e., La, may diffuse between the first interfacial layer 131A and the first high-k insulating film 132A. Accordingly, the first gate insulating layer 130A may include the metal material contained in the (1_1)-th conductivity-type metal oxide film 134A, i.e., La, between the first interfacial layer 131A and the first high-k insulating film 132A. The first high-k insulating film 132A may also include the metal material contained in the (1_1)-th conductivity-type metal oxide film 134A, i.e., La.

Due to the presence of the N-type dipole element, a dipole-interface may be formed between the first interfacial layer 131A and the first high-k insulating film 132A. When the (1_1)-th conductivity-type metal oxide film 134A contains La, the effective work function of the first gate electrode layer 120A may be reduced.

By providing the (1_1)-th conductivity-type metal oxide film 134A containing a low work function dipole element on the first peripheral active region P_ACT1, the threshold voltage of an N-type metal-oxide semiconductor field-effect transistor (NMOSFET) may be adjusted to be lowered.

The (1_2)-th conductivity-type metal oxide film 234A may include an oxide of an N-type dipole element. The (1_2)-th conductivity-type metal oxide film 234A may have a smaller oxygen content per unit volume than silicon oxide. For example, the N-type dipole element may include La, but is not limited thereto. In this case, the (1_2)-th conductivity-type metal oxide film 234A may include LaO. The (1_2)-th conductivity-type metal oxide film 234A may be formed in the same process as the (1_1)-th conductivity-type metal oxide film 134A.

The second conductivity-type metal oxide film 233A may include an oxide of a P-type dipole element. The second conductivity-type metal oxide film 233A may contain a material of a different conductivity type from the (1_1)-th conductivity-type metal oxide film 134A. The second conductivity-type metal oxide film 233A may have a greater oxygen content per unit volume than silicon oxide. For example, the P-type dipole element may include Al, but is not limited thereto. In this case, the second conductivity-type metal oxide film 233A may include aluminum oxide (AlO). When the second conductivity-type metal oxide film 233A contains Al, the effective work function of the second gate electrode layer 220A may be adjusted to be increased.

By providing the second conductivity-type metal oxide film 233A containing a high work function dipole element on the second peripheral active region P_ACT2, the threshold voltage of a P-type metal-oxide semiconductor field-effect transistor (PMOSFET) may be increased.

The second conductivity-type metal oxide film 233A may be arranged between the second high-k insulating film 232A and the (1_2)-th conductivity-type metal oxide film 234A. The second conductivity-type metal oxide film 233A may be arranged between the second high-k insulating film 232A and a second electrode film 221A, which will be described later.

For example, thicknesses T11 and T12 of the (1_1)-th and (1_2)-th conductivity-type metal oxide films 134A and 234A may be substantially the same. Each of the thicknesses T11 and T12 of the (1_1)-th and (1_2)-th conductivity-type metal oxide films 134A and 234A may be greater than a thickness T2 of the second conductivity-type metal oxide film 233A, but is not limited thereto. For example, the thicknesses T11, T12, and T2 may each be 10 A or less, but are not limited thereto.

The first gate electrode layer 120A may be arranged on the first gate insulating layer 130A. The second gate electrode layer 220A may be arranged on the second gate insulating layer 230A.

The first and second gate electrode layers 120A and 220A may include at least one of a metal, a conductive metal nitride, a conductive metal carbonitride, a conductive metal carbide, a metal silicide, a doped semiconductor material, a conductive metal oxide, or a conductive metal oxynitride. The first and second gate electrode layers 120A and 220A may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), Al, copper (Cu), cobalt (Co), Ti, tantalum (Ta), nickel (Ni), platinum (Pt), nickel platinum (NiPt), niobium (Nb), niobium nitride (NbN), niobium carbide (NbC), molybdenum (Mo), molybdenum nitride (MON), molybdenum carbide (MoC), tungsten carbide (WC), rhodium (Rh), palladium (Pd), iridium (Ir), osmium (Os), silver (Ag), gold (Au), zinc (Zn), vanadium (V), doped silicon, doped silicon germanium, doped germanium, or a combination thereof, but the present disclosure is not limited thereto. Here, the conductive metal oxide and conductive metal oxynitride may include oxidized forms of the aforementioned materials, but are not limited thereto.

The specific structures and materials of the first and second gate electrode layers 120A and 220A will hereinafter be described.

The first gate electrode layer 120A may be arranged on the (1_1)-th conductivity-type metal oxide film 134A. In some embodiments, the first gate electrode layer 120A may also be referred to as the (1_1)-th electrode film 120A. The first gate electrode layer 120A may include at least one of TiN, TiAlC, or TiAlN, but is not limited thereto.

The second gate electrode layer 220A may include a second electrode film 221A, a barrier film 222A, and a (1_2)-th electrode film 223A that are sequentially stacked on the second conductivity-type metal oxide film 233A. The (1_2)-th electrode film 223A may be arranged on the (1_2)-th conductivity-type metal oxide film 234A. The second electrode film 221A may be arranged on the second conductivity-type metal oxide film 233A.

The second electrode film 221A and the (1_2)-th electrode film 223A may each include at least one of TiN, TiAlC, or TiAlN, but are not limited thereto.

The (1_2)-th electrode film 223A may include the same material as the (1_1)-th electrode film 120A. The (1_2)-th electrode film 223A may be formed in the same process as the (1_1)-th electrode film 120A. Accordingly, the (1_2)-th electrode film 223A may have the same thickness and composition as the (1_1)-th electrode film 120A.

The thickness of the second electrode film 221A may differ from the thicknesses of the (1_1)-th electrode film 120A and the (1_2)-th electrode film 223A.

The (1_1)-th electrode film 120A, the (1_2)-th electrode film 223A, and the second electrode film 221A are illustrated as single films, but are not limited thereto.

The barrier film 222A may be arranged between the second high-k insulating film 232A and the (1_2)-th conductivity-type metal oxide film 234A. The barrier film 222A may be arranged between the second conductivity-type metal oxide film 233A and the (1_2)-th conductivity-type metal oxide film 234A. The barrier film 222A may be arranged between the second electrode film 221A and the (1_2)-th electrode film 223A. The barrier film 222A may be arranged between the second electrode film 221A and the (1_2)-th conductivity-type metal oxide film 234A.

The barrier film 222A may include a semimetal material. For example, the barrier film 222A may include at least one of PtSe₂, PdSe₂, or TiS₂, but is not limited thereto.

In some embodiments, by providing the barrier film 222A between the (1_2)-th conductivity-type metal oxide film 234A and the second high-k insulating film 232A, diffusion of the metal material from the (1_2)-th conductivity-type metal oxide film 234A into the second high-k insulating film 232A during heat treatment can be prevented.

Accordingly, the second gate insulating layer 230A may not include the metal material contained in the (1_2)-th conductivity-type metal oxide film 234A, between the second interfacial layer 231A and the second high-k insulating film 232A. The second high-k insulating film 232A may also not include the metal material contained in the (1_2)-th conductivity-type metal oxide film 234A, i.e., La.

Meanwhile, unlike the second transistor TRA2, the first transistor TRA1 may not include the barrier film 222A. Accordingly, as described above, the first gate insulating layer 130A may include the metal material contained in the (1_1)-th conductivity-type metal oxide film 134A, between the first interfacial layer 131A and the first high-k insulating film 132A.

In some embodiments, by preventing the diffusion of the metal material from the N-type dipole element in the PMOSFET, a reduction in the effective work function of the second gate electrode layer 220A may be prevented. That is, by additionally providing the barrier film 222A on the second gate insulating layer 230A, the threshold voltage of the PMOSFET may be adjusted to be increased. As a result, a semiconductor device capable of satisfying the target electrical characteristics of NMOS transistors and PMOS transistors may be formed.

A first gate mask pattern 145A may be arranged on the first gate electrode layer 120A. A second gate mask pattern 245A may be arranged on the second gate electrode layer 220A. The first and second gate mask patterns 145A and 245A may include an insulating material. For example, the first and second gate mask patterns 145A and 245A and may include silicon oxide, silicon oxynitride, or silicon nitride, but are not limited thereto.

First gate spacers 140A may be arranged on the sidewalls of the first gate electrode layer 120A. The first gate mask pattern 145A may be arranged between the first gate spacers 140A. Second gate spacers 240A may be arranged on the sidewalls of the second gate electrode layer 220A. The second gate mask pattern 245A may be arranged between the second gate spacers 240A.

The first gate spacers 140A and the second gate spacers 240A may include an insulating material. For example, the first gate spacers 140A and the second gate spacers 240A may each include at least one of silicon nitride (SiN), silicon oxynitride (SiON), silicon oxide (SiO₂), silicon oxycarbonitride (SiOCN), silicon boron nitride (SiBN), silicon oxynitride boron (SiOBN), or silicon oxycarbide (SiOC). The first gate spacers 140A and the second gate spacers 240A are illustrated as single films, but are not limited thereto.

The first source/drain regions 150A may be arranged on either side of the first gate electrode layer 120A. The first source/drain regions 150A may be formed in the substrate 100.

The first source/drain regions 150A may include N-type impurities. For example, the N-type impurities may include at least one of phosphorus (P), arsenic (As), antimony (Sb), or bismuth (Bi).

The second source/drain regions 250A may be arranged on either side of the second gate electrode layer 220A. The second source/drain regions 250A may be formed in the substrate 100.

The second source/drain regions 250A may be formed in the silicon germanium film 210A arranged on the top surface of the substrate 100. For example, portions of the second source/drain regions 250A may be arranged within the silicon germanium film 210A.

The second source/drain regions 250A may include P-type impurities. For example, the P-type impurities may include at least one of boron (B) or gallium (Ga).

A first interlayer insulating film 190A may be arranged on the substrate 100. The first interlayer insulating film 190A may be arranged over the first transistor TRA1. The first interlayer insulating film 190A may cover the first source/drain regions 150A, the first gate structure GSA1, and the first gate mask pattern 145A.

A second interlayer insulating film 290A may be arranged on the substrate 100. The second interlayer insulating film 290A may be arranged over the second transistor TRA2. The second interlayer insulating film 290A may cover the second source/drain regions 250A, the second gate structure GSA2, and the second gate mask pattern 245A.

The first and second interlayer insulating films 190A and 290A may include at least one of silicon oxide, silicon nitride, or silicon oxynitride.

Although not illustrated, the semiconductor device according to some embodiments may further include a first contact (not illustrated) penetrating the first interlayer insulating film 190A and connected to the first source/drain regions 150A. The semiconductor device according to some embodiments may further include a second contact (not illustrated) penetrating the second interlayer insulating film 290A and connected to the second source/drain regions 250A.

The first and second contacts may include, for example, a conductive material. The first and second contacts may include at least one of a metal, a conductive metal nitride, a conductive metal carbonitride, a conductive metal carbide, a metal silicide, a doped semiconductor material, a conductive metal oxide, a conductive metal oxynitride, or a two-dimensional (2D) material.

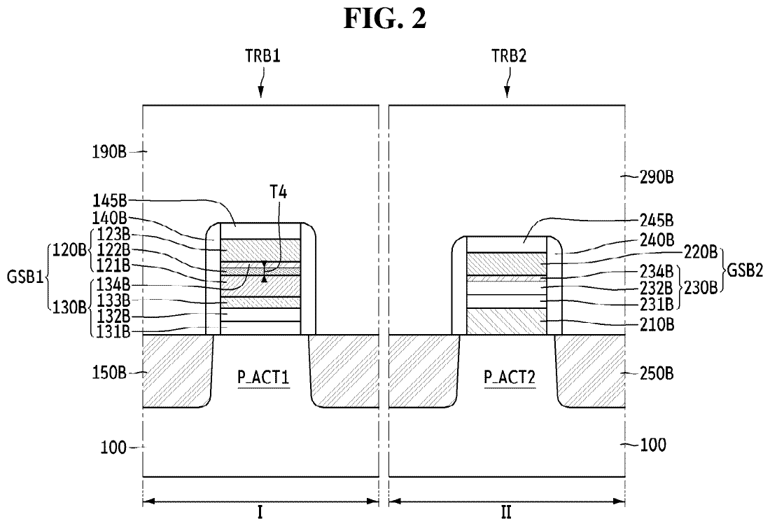

FIG. 2 is a diagram for explaining a semiconductor device according to some embodiments. For convenience, parts overlapping with those described above with reference to FIG. 1 will be briefly explained or omitted.

Referring to FIG. 2, the semiconductor device according to some embodiments may include a substrate 100, a first transistor TRB1, and a second transistor TRB2.

The substrate 100 may include a first region I and a second region II. The first and second regions I and II may be spaced apart from each other or may be connected to each other.

The substrate 100 may be a silicon substrate or an SOI substrate. Alternatively, the substrate 100 may include silicon germanium, SGOI, indium antimonide, a lead telluride compound, indium arsenide, indium phosphide, gallium arsenide, or gallium antimonide, but is not limited thereto.

The first transistor TRB1 may include a first gate structure GSB1 and first source/drain regions 150B. The second transistor TRB2 may include a second gate structure GSB2 and second source/drain regions 250B.

The first gate structure GSB1 may include a first gate insulating layer 130B and a first gate electrode layer 120B. The second gate structure GSB2 may include a second gate insulating layer 230B and a second gate electrode layer 220B.

The first gate insulating layer 130B, the first gate electrode layer 120B, and the first source/drain regions 150B may be arranged in the first region I of the substrate 100. A silicon germanium film 210B, the second gate insulating layer 230B, the second gate electrode layer 220B, and the second source/drain regions 250B may be arranged in the second region II of the substrate 100.

Although not illustrated, an element isolation film (not illustrated) may be arranged in the substrate 100. The substrate 100 may include an active region defined by the element isolation film. For example, the element isolation film may define a first peripheral active region P_ACT1 and a second peripheral active region P_ACT2.

The first peripheral active region P_ACT1 included in the first region I may be, for example, a region where an NMOS transistor is formed. The second peripheral active region P_ACT2 included in the second region II may be a region where PMOS transistor is formed.

The element isolation film may be formed as an STI structure. The element isolation film may extend in the thickness direction of the substrate 100 (e.g., the fourth direction D4 in FIG. 8).

The element isolation film may include at least one of silicon oxide, silicon nitride, silicon oxynitride, or a combination thereof.

The silicon germanium film 210B may be arranged on the second peripheral active region P_ACT2. The silicon germanium film 210B may be arranged on the top surface of the substrate 100. The silicon germanium film 210B may be in contact with the substrate 100.

The silicon germanium film 210B may include silicon germanium. For example, the silicon germanium film 210B may include a monocrystalline silicon germanium film.

In one example, the silicon germanium film 210B may include doped p-type and/or n-type impurities. In another example, the silicon germanium film 210B may be formed as an undoped silicon germanium film.

The first gate insulating layer 130B may include a first interfacial layer 131B, a first high-k insulating film 132B, a first conductivity-type metal oxide film 133B, and a (2_1)-th conductivity-type metal oxide film 134B that are sequentially arranged on the substrate 100. The first interfacial layer 131B may be arranged between the substrate 100 and the first high-k insulating film 132B.

The second gate insulating layer 230B may include a second interfacial layer 231B, a second high-k insulating film 232B, and a (2_2)-th conductivity-type metal oxide film 234B that are sequentially arranged on the substrate 100.

The second interfacial layer 231B may be arranged between the silicon germanium film 210B and the second high-k insulating film 232B. The second interfacial layer 231B may be in contact with the silicon germanium film 210B. For example, the second interfacial layer 231B may be in direct contact with the top surface of the silicon germanium film 210B. The first and second interfacial layers 131B and 231B may each include, for example, a silicon oxide film.

The first and second high-k insulating films 132B and 232B may each include a high-k material with a higher dielectric constant than silicon oxide. The high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include NCFETs using a negative capacitor. For example, the first and second high-k insulating films 132B and 232B may each include a ferroelectric material film having ferroelectric properties and a paraelectric material film having paraelectric properties.

In one example, the first and second gate insulating layers 130B and 230B may each include a single ferroelectric material film. In another example, the first and second gate insulating layers 130B and 230B may each include multiple ferroelectric material films spaced apart from each other. The first and second gate insulating layers 130B and 230B may each include a stacked film structure in which multiple ferroelectric material films and multiple paraelectric material films are alternately stacked.

The (2_2)-th conductivity-type metal oxide film 234B may include an oxide of a P-type dipole element. The (2_2)-th conductivity-type metal oxide film 234B may have a greater oxygen content per unit volume than silicon oxide. For example, the P-type dipole element may include Al, but is not limited thereto. In this case, the (2_2)-th conductivity-type metal oxide film 234B may include AIO. The (2_2)-th conductivity-type metal oxide film 234B may diffuse the P-type dipole element into the second gate insulating layer 230B. When the (2_2)-th conductivity-type metal oxide film 234B contains Al, the effective work function of the second gate electrode layer 220A may be increased.

Through a heat treatment process, the metal material contained in the (2_2)-th conductivity-type metal oxide film 234B, i.e., Al, may diffuse between the second interfacial layer 231B and the second high-k insulating film 232B. Accordingly, the second gate insulating layer 230B may include the metal material contained in the (2_2)-th conductivity-type metal oxide film 234B, i.e., Al, between the second interfacial layer 231B and the second high-k insulating film 232B. The second high-k insulating film 232B may also include the metal material contained in the (2_2)-th conductivity-type metal oxide film 234B, i.e., Al.

Due to the presence of the N-type dipole element, a dipole-interface may be formed between the second interfacial layer 231B and the second high-k insulating film 232B. When the (2_2)-th conductivity-type metal oxide film 234B contains Al, the effective work function of the second gate electrode layer 220B may be increased.

By providing the (2_2)-th conductivity-type metal oxide film 234B containing a high work function dipole element on the second peripheral active region P_ACT2, the threshold voltage of a PMOSFET may be adjusted to be increased.

The (2_1)-th conductivity-type metal oxide film 134B may include an oxide of a P-type dipole element. The (2_1)-th conductivity-type metal oxide film 134B may have a greater oxygen content per unit volume than silicon oxide. For example, the P-type dipole element may include Al, but is not limited thereto. In this case, the (2_1)-th conductivity-type metal oxide film 134B may include AIO. The (2_1)-th conductivity-type metal oxide film 134B may be formed in the same process as the (2_2)-th conductivity-type metal oxide film 234B.

The first conductivity-type metal oxide film 133B may include an oxide of an N-type dipole element. The first conductivity-type metal oxide film 133B may have a smaller oxygen content per unit volume than silicon oxide. For example, the N-type dipole element may include La, but is not limited thereto. In this case, the first conductivity-type metal oxide film 133B may include LaO. The first conductivity-type metal oxide film 133B may lower the effective work function of the first gate insulating layer 130B.

By providing the first conductivity-type metal oxide film 133B containing a low work function dipole element on the first peripheral active region P_ACT1, the threshold voltage of an NMOSFET may be adjusted to be lowered.

The first conductivity-type metal oxide film 133B may be arranged between the first high-k insulating film 132B and the (2_1)-th conductivity-type metal oxide film 134B. The first conductivity-type metal oxide film 133B may be arranged between the first high-k insulating film 132B and a second electrode film 121B, which will be described later.

For example, the (2_1)-th and (2_2)-th conductivity-type metal oxide films 134B and 234B may have substantially the same thickness. For example, the thicknesses of the (2_1)-th and (2_2)-th conductivity-type metal oxide films 134B and 234B may be smaller than the thickness of the first conductivity-type metal oxide film 133B, but are not limited thereto. For example, the thicknesses of the (2_1)-th and (2_2)-th conductivity-type metal oxide films 134B and 234B and the first conductivity-type metal oxide film 133B may each be 10 A or less, but are not limited thereto.

The first gate electrode layer 120B may be arranged on the first gate insulating layer 130B. The second gate electrode layer 220B may be arranged on the second gate insulating layer 230B.

The first and second gate electrode layers 120B and 220B may include at least one of a metal, a conductive metal nitride, a conductive metal carbonitride, a conductive metal carbide, a metal silicide, a doped semiconductor material, a conductive metal oxide, or a conductive metal oxynitride. The first and second gate electrode layers 120B and 220B may include, for example, at least one of TiN, TaC, TaN, TiSiN, TaSiN, TaTiN, TiAlN, TaAlN, WN, Ru, TiAl, TiAlCN, TiAlC, TiC, TaCN, W, Al, Cu, Co, Ti, Ta, Ni, Pt, NiPt, Nb, NbN, NbC, Mo, MoN, MoC, WC, Rh, Pd, Ir, Os, Ag, Au, Zn, V, doped silicon, doped silicon germanium, doped germanium, or a combination thereof, but the present disclosure is not limited thereto. Here, the conductive metal oxide and conductive metal oxynitride may include oxidized forms of the aforementioned materials, but are not limited thereto.

The specific structures and materials of the first and second gate electrode layers 120B and 220B will hereinafter be described.

The second gate electrode layer 220B may be arranged on the (2_2)-th conductivity-type metal oxide film 234B. In some embodiments, the second gate electrode layer 220B may also be referred to as the (1_1)-th electrode film 220B. The second gate electrode layer 220B may include at least one of TiN, TiAlC, or TiAlN, but is not limited thereto.

The first gate electrode layer 120B may include a second electrode film 121B, a barrier film 122B, and a (1_2)-th electrode film 123B that are sequentially stacked on the first conductivity-type metal oxide film 133B. The (1_2)-th electrode film 123B may be arranged on the (2_1)-th electrode film 134B. The second electrode film 121B may be arranged on the first conductivity-type metal oxide film 133B.

The second electrode film 121B and the (1_2)-th electrode film 123B may each include at least one of TiN, TiAlC, or TiAlN, but are not limited thereto.

The (1_2)-th electrode film 123B may include the same material as the (1_1)-th electrode film 220B. The (1_2)-th electrode film 123B may be formed in the same process as the (1_1)-th electrode film 220B. Accordingly, the (1_2)-th electrode film 123B may have the same thickness and composition as the (1_1)-th electrode film 220B.

The thickness of the second electrode film 121B may differ from the thicknesses of the (1_1)-th electrode film 220B and the (1_2)-th electrode film 123B.

The (1_1)-th electrode film 220B, the (1_2)-th electrode film 123B, and the second electrode film 121B are illustrated as single films, but are not limited thereto.

The barrier film 122B may be arranged between the first high-k insulating film 132B and the (2_1)-th electrode film 134B. The barrier film 122B may be arranged between the first conductivity-type metal oxide film 133B and the (2_1)-th electrode film 134B. The barrier film 122B may be arranged between the second electrode film 121B and the (1_2)-th electrode film 123B. The barrier film 122B may be arranged between the second electrode film 121B and the (2_1)-th electrode film 134B.

The barrier film 122B may include a semimetal material. For example, the barrier film 122B may include at least one of PtSe₂, PdSe₂, or TiS₂, but is not limited thereto.

A thickness T3 of the barrier film 222A in FIG. 1 may be smaller than a thickness T4 of the barrier film 122B in FIG. 2, but the present disclosure is not limited thereto.

In some embodiments, by providing the barrier film 122B between the (2_1)-th electrode film 134B and the first high-k insulating film 132B, diffusion of the metal material from the (2_1)-th electrode film 134B into the first high-k insulating film 132B during heat treatment can be prevented.

Accordingly, the first gate insulating layer 130B may not include the metal material contained in the (2_1)-th electrode film 134B, between the first interfacial layer 131B and the first high-k insulating film 132B. The first high-k insulating film 132B may also not include the metal material contained in the (2_1)-th electrode film 134B, i.e., Al.

Meanwhile, unlike the first transistor TRB1, the second transistor TRB2 may not include the barrier film 122B. Accordingly, as described above, the second gate insulating layer 230B may include the metal material contained in the (2_2)-th conductivity-type metal oxide film 234B, between the second interfacial layer 231B and the second high-k insulating film 232B.

In some embodiments, by preventing the diffusion of the metal material from the P-type dipole element in the NMOSFET, a reduction in the effective work function of the first gate electrode layer 120B may be prevented. That is, by additionally providing the barrier film 122B on the first gate insulating layer 130B, the threshold voltage of the NMOSFET may be adjusted to be lowered. As a result, a semiconductor device capable of satisfying the target electrical characteristics of NMOS transistors and PMOS transistors may be formed.

A first gate mask pattern 145B may be arranged on the first gate electrode layer 120B. A second gate mask pattern 245B may be arranged on the first gate electrode layer 120B. The first and second gate mask patterns 145B and 245B may include an insulating material. For example, the first and second gate mask patterns 145B and 245B and may include silicon oxide, silicon oxynitride, or silicon nitride, but are not limited thereto.

First gate spacers 140B may be arranged on the sidewalls of the first gate electrode layer 120B. The first gate mask pattern 145B may be arranged between the first gate spacers 140B. Second gate spacers 240B may be arranged on the sidewalls of the first gate electrode layer 120B. The second gate mask pattern 245B may be arranged between the second gate spacers 240B.

The first gate spacers 140B and the second gate spacers 240B may include an insulating material. For example, the first gate spacers 140B and the second gate spacers 240B may each include at least one of SiN, SiON, SiO2, SiOCN, SiBN, SiOBN, or SiOC. The first gate spacers 140B and the second gate spacers 240B are illustrated as single films, but are not limited thereto.

The first source/drain regions 150B may be arranged on either side of the first gate electrode layer 120B. The first source/drain regions 150B may be formed in the substrate 100.

The first source/drain regions 150B may include N-type impurities. For example, the N-type impurities may include at least one of P, As, Sb, or Bi.

The second source/drain regions 250B may be arranged on either side of the first gate electrode layer 120B. The second source/drain regions 250B may be formed in the substrate 100.

The second source/drain regions 250B may be formed in the silicon germanium film 210B arranged on the top surface of the substrate 100. For example, portions of the second source/drain regions 250B may be arranged within the silicon germanium film 210B.

The second source/drain regions 250B may include P-type impurities. For example, the P-type impurities may include at least one of B or Ga.

A first interlayer insulating film 190B may be arranged on the substrate 100. The first interlayer insulating film 190B may be arranged over the first transistor TRB1. The first interlayer insulating film 190B may cover the first source/drain regions 150A, the first gate structure GSA1, and the first gate mask pattern 145B.

A second interlayer insulating film 290B may be arranged on the substrate 100. The second interlayer insulating film 290B may be arranged over the second transistor TRB2. The second interlayer insulating film 290B may cover the second source/drain regions 250B, the second gate structure GSB2, and the second gate mask pattern 245B.

The first and second interlayer insulating films 190B and 290B may include at least one of silicon oxide, silicon nitride, or silicon oxynitride.

Although not illustrated, the semiconductor device according to some embodiments may further include a first contact (not illustrated) penetrating the first interlayer insulating film 190B and connected to the first source/drain regions 150B. The semiconductor device according to some embodiments may further include a second contact (not illustrated) penetrating the second interlayer insulating film 290B and connected to the second source/drain regions 250B.

The first and second contacts may include, for example, a conductive material. The first and second contacts may include at least one of a metal, a conductive metal nitride, a conductive metal carbonitride, a conductive metal carbide, a metal silicide, a doped semiconductor material, a conductive metal oxide, a conductive metal oxynitride, or a 2D material.

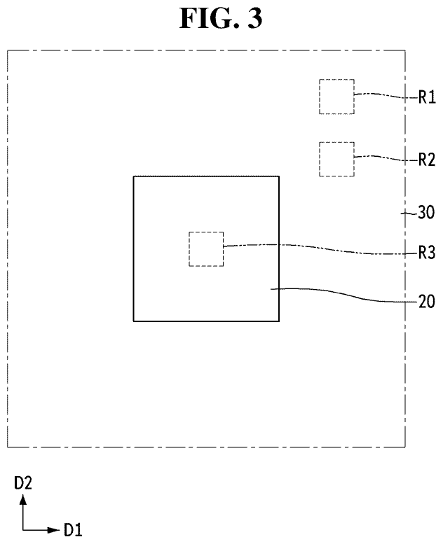

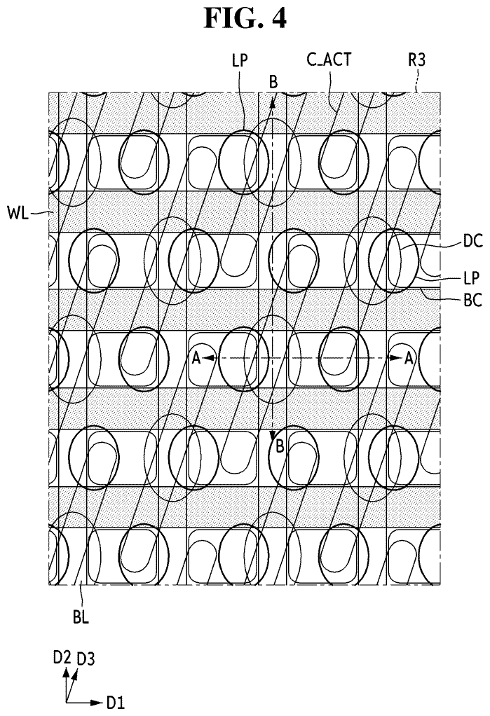

FIG. 3 is a schematic layout diagram illustrating a semiconductor device according to some embodiments. FIG. 4 is an enlarged schematic layout diagram of region R3 in FIG. 3.

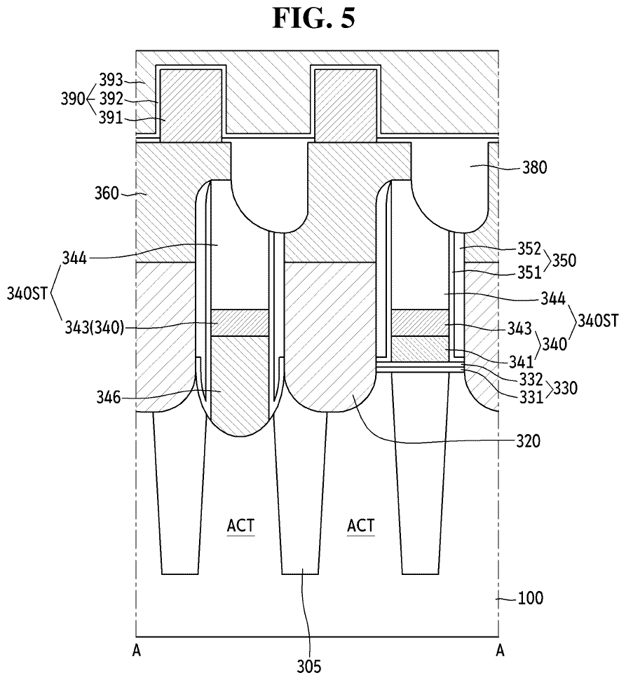

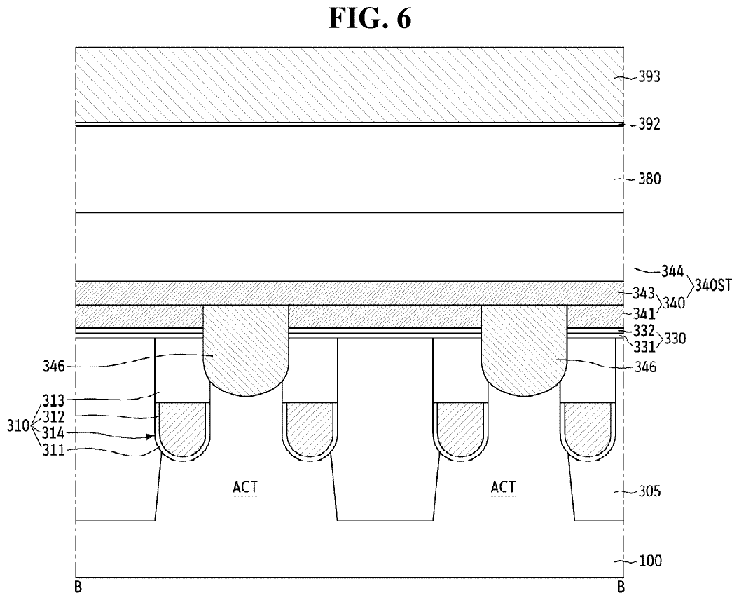

FIG. 5 is a cross-sectional view taken along line A-A of FIG. 4. FIG. 6 is a cross-sectional view taken along line B-B of FIG. 4.

For reference, a dynamic random access memory (DRAM) is illustrated as an exemplary semiconductor device according to some embodiments, but the present disclosure is not limited thereto. Additionally, FIG. 4 illustrates the layout of the semiconductor device according to some embodiments, with a first capacitor 390 omitted.

Referring to FIG. 3, the semiconductor device according to some embodiments may include a cell region 20 and a peripheral region 30 defined around the cell region 20.

In other words, a substrate (“100” in FIG. 1) may include a memory cell region 20 and a peripheral region 30. For example, the memory cell region 20 may be a region where memory cells are arranged. The peripheral region 30 may be a region where circuits for operating the memory cells of the memory cell region 20 are arranged.

A cross-sectional view, taken along a first direction D1 or a second direction D2, of region R1 of FIG. 3 may be a first cross-sectional view. A cross-sectional view, taken along the first direction D1 or the second direction D2, of region R2 of FIG. 3 may be as a second cross-sectional view. The first direction D1 may intersect the second direction D2.

In one example, the first cross-sectional view may correspond to a cross-sectional view of the first region I in FIG. 1, and the second cross-sectional view may correspond to a cross-sectional view of the second region II in FIG. 1. That is, the first and second peripheral active regions P_ACT1 and P_ACT2 in FIG. 1 may be positioned in region R1 and region R2, respectively, in FIG. 3, but the present disclosure is not limited thereto.

In other words, the semiconductor device described with reference to FIGS. 1 and 2 may be arranged in the peripheral region 30 in FIG. 3.

The descriptions of regions R1 and R2 in FIG. 3 are similar to those provided with reference to FIGS. 1 and 2, and thus, the following description focuses on region R3 in FIG. 3.

Referring to FIG. 4, the semiconductor device according to some embodiments may include a plurality of first cell active regions C_ACT. The first cell active regions C_ACT may be defined by second element isolation films 305 formed in the substrate 100.

As the design rule of the semiconductor device according to some embodiments is reduced, the first cell active regions C_ACT may be arranged in a bar shape extending along a diagonal (or oblique) line, as illustrated. The first cell active regions C_ACT may have a bar shape extending in a third direction D3.

A plurality of gate electrodes may be arranged across the first cell active regions C_ACT along the first direction D1. The gate electrodes may extend in parallel with each other. The gate electrodes may, for example, correspond to a plurality of wordlines WL.

The wordlines WL may be arranged at equal intervals. The width of the wordlines WL and the spacing between the wordlines WL may be determined according to the design rule.

A plurality of bitlines BL extending in the second direction D2, which is orthogonal to the wordlines WL, may be arranged on the wordlines WL. The bitlines BL may extend across the first cell active regions C_ACT in the second direction D2.

The bitlines BL may extend in parallel with each other. The bitlines BL may be arranged at equal intervals. The width of the bitlines BL and the spacing between the bitlines BL may be determined according to the design rule.

The semiconductor device according to some embodiments may include various contact arrangements formed on the first cell active regions C_ACT. The various contact arrangements may include, for example, direct contacts DC, buried contacts BC, and landing pads LP.

Here, the direct contacts DC may refer to contacts electrically connecting the first cell active regions C_ACT to the bitlines BL. The buried contacts BC may refer to contacts connecting the first cell active regions C_ACT to first lower electrodes 391 of the first capacitor 390 (in FIG. 5).

Due to the layout structure, the contact area between the buried contacts BC and the first cell active regions C_ACT may be relatively small. Accordingly, to enlarge the contact area with the first cell active regions C_ACT as well as the contact area with the first lower electrodes 391 of the first capacitor 390, the conductive landing pads LP may be introduced.

The landing pads LP may be arranged between the first cell active regions C_ACT and the buried contacts BC, or between the buried contacts BC and the first lower electrodes 391 of the first capacitor 390. In the semiconductor device according to some embodiments, the landing pads LP may be arranged between the buried contacts BC and the first lower electrodes 391 of the first capacitor 390. By introducing the landing pads LP, contact area can be increased, thereby reducing the contact resistance between the first cell active regions C_ACT and the first lower electrodes 391.

In the semiconductor device according to some embodiments, the direct contacts DC may be arranged in the central portions of the first cell active regions C_ACT, and the buried contacts BC may be arranged at both end portions of the first cell active regions C_ACT. Since the buried contacts BC are arranged at both end portions of the first cell active regions C_ACT, the landing pads LP may be arranged adjacent to both ends of the first cell active regions C_ACT, overlapping the buried contacts BC. In other words, the buried contacts BC may be formed so as to overlap the first cell active regions C_ACT and the second element isolation films 305, located between adjacent wordlines WL or between adjacent bitlines BL.

The wordlines WL may be formed to be buried in the substrate 100. The wordlines WL may be arranged across the first cell active regions C_ACT between the direct contacts DC and the buried contacts BC.

As illustrated, two wordlines WL may be arranged to cross one first cell active region C_ACT. Since the first cell active regions C_ACT are arranged diagonally, the wordlines WL may have an angle of less than 90 degrees with respect to the first cell active regions C_ACT.

The direct contacts DC and the buried contacts BC may be arranged symmetrically. Accordingly, the direct contacts DC and the buried contacts BC may be arranged in a straight line along the first and second directions D1 and D2.

Meanwhile, unlike the direct contacts DC and the buried contacts BC, the landing pads LP may be arranged in a zigzag pattern in the second direction D2, along which the bitlines BL extend. Additionally, in the first direction D1, along which the wordlines WL extend, the landing pads LP may be arranged to overlap the same side portions of the bitlines BL.

For example, landing pads LP in a first row may overlap the left side of a corresponding bitline BL, and landing pads LP in a second row may overlap the right side of the corresponding bitline BL.

Referring to FIGS. 4 through 6, the semiconductor device according to some embodiments may include the second element isolation films 305, a plurality of gate structures 310, a plurality of bitline structures 340ST, bitline contacts 346, storage contacts 320, and the first capacitor 390.

The first cell active regions C_ACT, defined by the second element isolation films 305, may each have an elongated island shape, including a short axis and a long axis, as illustrated in FIG. 4. The first cell active regions C_ACT may be diagonally arranged to form an angle of less than 90 degrees with respect to the wordlines WL, which are formed in the second element isolation films 305. Additionally, the first cell active regions C_ACT may be diagonally arranged to form an angle of less than 90 degrees with respect to the bitlines BL, which are formed on the second element isolation films 305.

The gate structures 310 may be formed in the substrate 100 and the second element isolation films 305. The gate structures 310 may be formed across the second element isolation films 305 and the first cell active regions C_ACT defined by the second element isolation films 305. That is, the gate structures 310 may be formed in the substrate 100 and the second element isolation films 305 in the first direction D1, in which the gate structures 310 extend.

The gate structures 310 may include gate trenches 314, third gate insulating films 311, third gate electrodes 312, and gate capping patterns 313, which are formed in the substrate 100 and the second element isolation films 305. Here, the third gate electrodes 312 may correspond to the wordlines WL.

The third gate insulating films 311 may extend along the sidewalls and the bottom surfaces of the gate trenches 314. The third gate insulating films 311 may include at least one of silicon oxide, silicon nitride, silicon oxynitride, or a high-k material with a higher dielectric constant than silicon oxide. The high-k material may be the same as described above with regard to the first and second high-k insulating films 132A and 232A in FIG. 1.

The third gate electrodes 312 may be arranged on the third gate insulating films 311. The third gate electrodes 312 may partially fill the gate trenches 314. The third gate electrodes 312 may include at least one of a metal, a conductive metal nitride, a conductive metal carbonitride, a conductive metal carbide, a metal silicide, a doped semiconductor material, a conductive metal oxynitride, or a conductive metal oxide. The third gate electrodes 312 may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto.

Although not illustrated, impurity-doped regions may be formed on at least one side of each of the gate structures 310. The impurity-doped regions may correspond to the source/drain regions of transistors.

The gate capping patterns 313 may be arranged on the third gate electrodes 312. The gate capping patterns 313 may fill portions of the gate trenches 314 that remain empty after the formation of the third gate electrodes 312. The gate capping patterns 313 may include an insulating material.

The bitline structures 340ST may include cell conductive lines 340 and cell line capping films 344. The cell conductive lines 340 may be arranged on the substrate 100 and the second element isolation films 305 where the gate structures 310 are arranged. The cell conductive lines 340 may intersect the first cell active regions C_ACT defined by the second element isolation films 305. The cell conductive lines 340 may be arranged on the substrate 100 and the second element isolation films 305 in the second direction D2, in which the cell conductive lines 340 extend. The cell conductive lines 340 may be formed to intersect the gate structures 310. Here, the cell conductive lines 340 may correspond to the bitlines BL.

The cell conductive lines 340 may include lower cell conductive lines 341 and upper cell conductive lines 343 on the lower cell conductive lines 341. In the semiconductor device according to some embodiments, the cell conductive lines 340 may have the same stacked structure as parts of the first gate electrodes 120.

In other words, when the conductive materials for forming the cell conductive lines 340 in the cell region 20 (in FIG. 3) are formed, some of the conductive materials for forming the first gate electrodes 120 in the peripheral region 30 (in FIG. 3) may also be formed.

The bitline contacts 346 may be arranged between the cell conductive lines 340 and the substrate 100. That is, the cell conductive lines 340 may be formed on the bitline contacts 346. For example, the bitline contacts 346 may be arranged at points where the cell conductive lines 340 intersect the central portions of the first cell active regions C_ACT, which have an elongated island shape. The bitline contacts 346 may be formed between the cell conductive lines 340 and portions of the substrate 100 at the central portions of the first cell active regions C_ACT. The bitline contacts 346 may electrically connect the cell conductive lines 340 and the substrate 100. Through the bitline contacts 346, the bitline structures 340ST may be connected to the first cell active regions C_ACT. The bitline contacts 346 may correspond to the direct contacts DC. The bitline contacts 346 may include at least one of a doped semiconductor material, a conductive silicide compound, a conductive metal nitride, a conductive metal oxide, or a metal.

The cell line capping films 344 may be arranged on the cell conductive lines 340. The cell line capping films 344 may include an insulating material.

Cell insulating films 330 may be arranged on the substrate 100 and the second element isolation films 305. The cell insulating films 330 may be formed on the substrate 100 and the second element isolation films 305 where the bitline contacts 346 are not formed. The cell insulating films 330 may be formed between the substrate 100 and the cell conductive lines 340 and between the second element isolation films 305 and the cell conductive lines 340. The cell insulating films 330 may be single-layer films. Alternatively, as illustrated, the cell insulating films 330 may be multilayer films each including a first cell insulating film 331 and a second cell insulating film 332. For example, the first cell insulating films 331 may include, but are not limited to, oxide films, and the second cell insulating films 332 may include, but are not limited to, nitride films.

Cell line spacers 350 may be arranged on the sidewalls of the cell conductive lines 340 and the sidewalls of the cell line capping films 344. The cell line spacers 350 may be single-layer films. Alternatively, the cell line spacers 350 may be multilayer films including first cell line spacers 351 and second cell line spacers 352. For example, the first cell line spacers 351 and the second cell line spacers 352 may each include at least one of a silicon oxide film, a silicon nitride film, a SiON film, a SiOCN film, air, or a combination thereof, but the present disclosure is not limited thereto.

The storage contacts 320 may be arranged between adjacent cell conductive lines 340. The storage contacts 320 may overlap the substrate 100 and the second element isolation films 305 located between the adjacent cell conductive lines 340. Here, the storage contacts 320 may correspond to the buried contacts BC. The storage contacts 320 may include at least one of a doped semiconductor material, a conductive silicide compound, a conductive metal nitride, a conductive metal oxide, or a metal.

Storage pads 360 may be arranged on the storage contacts 320. The storage pads 360 may be electrically connected to the storage contacts 320. Here, the storage pads 360 may correspond to the landing pads LP. The storage pads 360 may include at least one of a doped semiconductor material, a conductive silicide compound, a conductive metal nitride, a conductive metal oxide, or a metal.

Pad isolation insulating films 380 may be arranged on the storage pads 360 and the bitline structures 340ST. For example, the pad isolation insulating films 380 may be arranged on the cell line capping films 344. The pad isolation insulating films 380 may define regions of the storage pads 360 that form a plurality of isolated areas. Additionally, the pad isolation insulating films 380 may be patterned to expose at least portions of the upper surfaces of the storage pads 360. The pad isolation insulating films 380 may include an insulating material.

The first capacitor 390 may be arranged on the pad isolation insulating films 380. The first capacitor 390 may be electrically connected to the storage contacts 320 through the storage pads 360. The first capacitor 390 may include first lower electrodes 391, a first capacitor dielectric film 392, and a first upper electrode 393.

The first lower electrodes 391 may be arranged on the storage pads 360. The first lower electrodes 391 are illustrated as having a pillar shape, but the present disclosure is not limited thereto. The first lower electrodes 391 may also have a cylindrical shape. The first capacitor dielectric film 392 may be arranged on the first lower electrode 391. The first capacitor dielectric film 392 may be formed along the profile of the first lower electrode 391. The first upper electrode 393 may be arranged on the first capacitor dielectric film 392. The first upper electrode 393 may surround the outer sidewalls of the first lower electrodes 391.

The first lower electrodes 391 and the first upper electrode 393 may each include, for example, at least one of a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide), but the present disclosure is not limited thereto.

The first capacitor dielectric film 392 may include, for example, at least one of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but the present disclosure is not limited thereto.

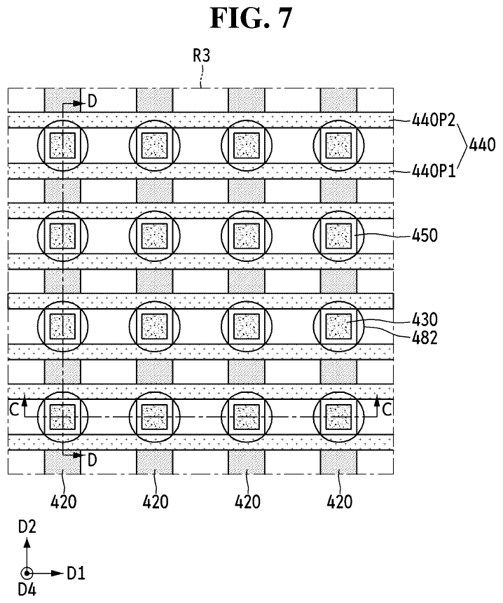

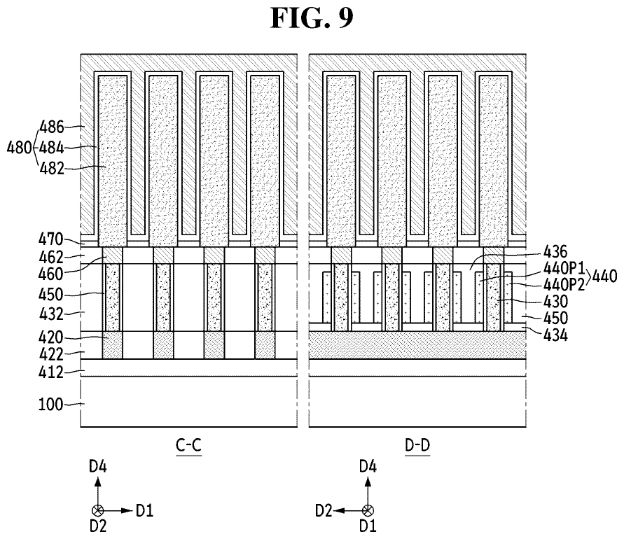

FIG. 7 is a layout diagram illustrating a semiconductor device according to some embodiments. FIG. 8 is a perspective view illustrating the semiconductor device according to some embodiments. FIG. 9 is a cross-sectional view taken along lines C-C and D-D of FIG. 7. For reference, FIG. 7 may be an enlarged layout diagram of region R3 (in FIG. 3) of the semiconductor device according to some embodiments.

Referring to FIGS. 7 through 9, the semiconductor device according to some embodiments may include a substrate 100, a plurality of first conductive lines 420, channel layers 430, fourth gate electrodes 440, fourth gate insulating films 450, and a second capacitor 480. The semiconductor device according to some embodiments may be a memory device including vertical channel transistors (VCTs). The VCTs may refer to structures in which the channel length of the channel layers 430 is oriented in a vertical direction from the substrate 100.

A lower insulating layer 412 may be arranged on the substrate 100. A plurality of first conductive lines 420 may be spaced apart from each other in a first direction D1 and may extend in a second direction D2 on the lower insulating layer 412. A plurality of first insulating patterns 422 may be arranged on the lower insulating layer 412 to fill spaces between the first conductive lines 420. The first insulating patterns 422 may extend in the second direction D2.

The top surfaces of the first insulating patterns 422 may be arranged at the same level as the top surfaces of the first conductive lines 420. The first conductive lines 420 may function as bitlines.

The first conductive lines 420 may include a doped semiconductor material, a metal, a conductive metal nitride, a conductive metal silicide, a conductive metal oxide, or a combination thereof. For example, the plurality of first conductive lines 420 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto. The first conductive lines 420 may each include a single layer or multiple layers of the aforementioned materials. In exemplary embodiments, the first conductive lines 420 may include graphene, carbon nanotubes, or a combination thereof.

The channel layers 430 may be arranged in a matrix form to be spaced apart from each other in the first and second directions D1 and D2, on the first conductive lines 420. The channel layers 430 may have a first width in the first direction D1 and a first height in a fourth direction D4, and the first height may be greater than the first width. Here, the fourth direction D4 may intersect the first and second directions D1 and D2 and may be, for example, a direction perpendicular to the top surface of the substrate 100. For example, the first height may be approximately 2 to 10 times the first width, but the present disclosure is not limited thereto. Bottom portions of the channel layers 430 may function as third source/drain regions (not illustrated), and upper portions of the channel layers 430 may function as fourth source/drain regions (not illustrated). Portions of the channel layers 430 between the third source/drain regions and the fourth source/drain regions may function as channel regions (not illustrated).

In exemplary embodiments, the channel layers 430 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. The channel layers 430 may each include a single layer or multiple layers of the oxide semiconductor. In some examples, the channel layers 430 may have a greater bandgap energy than silicon. For example, the channel layers 430 may have a bandgap energy of approximately 1.5 eV to 5.6 eV. For example, the channel layers 430 may exhibit optimal channel performance when having a bandgap energy of approximately 2.0 eV to 4.0 eV. The channel layers 430 may be polycrystalline or amorphous, but the present disclosure is not limited thereto. In exemplary embodiments, the channel layers 430 may include graphene, carbon nanotubes, or a combination thereof.

The fourth gate electrodes 440 may extend in the first direction D1 along both sidewalls of the channel layers 430. The second gate electrodes 440 may include first sub-gate electrodes 440P1 facing first sidewalls of the channel layers 430 and second sub-gate electrodes 440P2 facing second sidewalls opposite to the first sidewalls. Since a single channel layer 430 is arranged between first and second sub-gate electrodes 440P1 and 440P2 of each fourth gate electrode 440, the semiconductor device according to some embodiments may have a dual-gate transistor structure, but the present disclosure is not limited thereto. The second sub-gate electrodes 440P2 may be omitted so that only the first sub-gate electrodes 440P1 that face the first sidewalls of the channel layers 430 may be formed, thereby implementing single-gate transistor structures. The material included in the fourth gate electrodes 440 may be the same as described above with regard to the third gate electrodes 312.

The fourth gate insulating films 450 may surround the sidewalls of the channel layers 430 and may be positioned between the channel layers 430 and the fourth gate electrodes 440. For example, as illustrated in FIG. 9, the entire sidewalls of the channel layers 430 may be surrounded by the fourth gate insulating films 450, and parts of the sidewalls of the fourth gate electrodes 440 may be in contact with the fourth gate insulating films 450. In other embodiments, the fourth gate insulating films 450 may extend in the direction in which the fourth gate electrodes 440 extend (i.e., the first direction D1), such that only two sidewalls of each of the channel layers 430 facing the corresponding fourth gate electrode 440 may be in contact with the corresponding fourth gate insulating film 450. In exemplary embodiments, the fourth gate insulating films 450 may each include a silicon oxide film, a silicon oxynitride film, a high-k material having a higher dielectric constant than silicon oxide, or a combination thereof.

A plurality of second insulating patterns 432 may extend in the second direction D2 on the first insulating patterns 422. A channel layer 430 may be arranged between two adjacent second insulating patterns 432. Additionally, between the two adjacent second insulating patterns 432, a first filling layer 434 and a second filling layer 436 may be arranged in the space between two adjacent channel layers 430. The first filling layer 434 may be arranged at the bottom of the space between the two adjacent channel layers 430. The second filling layer 436 may be formed on the first filling layer 434 to fill the remaining space between the two adjacent channel layers 430. The top surface of the second filling layer 436 may be arranged at the same level as the top surfaces of the channel layers 430, and the second filling layer 436 may cover the top surfaces of the fourth gate electrodes 440. Alternatively, the second insulating patterns 432 may be formed as continuous material layers with the first insulating patterns 422, or the second filling layers 436 may be formed as continuous material layers with the first filling layers 434.

Capacitor contacts 460 may be arranged on the channel layers 430. The capacitor contacts 460 may be placed to vertically overlap the channel layers 430 and may be arranged in a matrix form to be spaced apart in the first and second directions D1 and D2. The capacitor contacts 460 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto. Upper insulating layers 462 may surround the sidewalls of the capacitor contacts 460 on the second insulating patterns 432 and the second filling layers 436.

An etch stop film 470 may be arranged on the upper insulating layers 462. A second capacitor 480 may be arranged on the etch stop film 470. The second capacitor 480 may include second lower electrodes 482, a second capacitor dielectric film 484, and a second upper electrode 486. The second lower electrodes 482 may penetrate the etch stop film 470 to be electrically connected to the top surfaces of the capacitor contacts 460. The second lower electrodes 482 may be formed in a pillar shape extending in the fourth direction D4, but the present disclosure is not limited thereto. In exemplary embodiments, the second lower electrodes 482 may be placed to vertically overlap the capacitor contacts 460 and may be arranged in a matrix form to be spaced apart in the first and second directions D1 and D2. Alternatively, landing pads (not illustrated) may be further arranged between the capacitor contacts 460 and the second lower electrodes 482, and the second lower electrodes 482 may be arranged in a hexagonal shape.

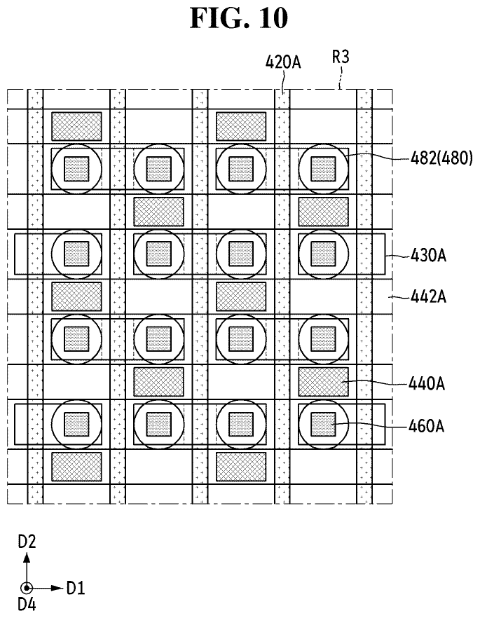

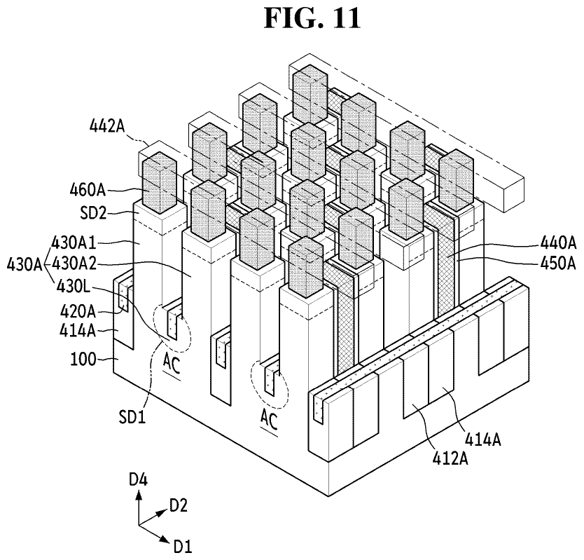

FIG. 10 is a layout diagram illustrating a semiconductor device according to some embodiments. FIG. 11 is a perspective view illustrating the semiconductor device according to some embodiments.

Referring to FIGS. 10 and 11, the semiconductor device according to some embodiments may include a substrate 100, a plurality of first conductive lines 420A, channel structures 430A, contact gate electrodes 440A, a plurality of second conductive lines 442A, and a second capacitor 480. The semiconductor device according to some embodiments may be a memory device including VCTs.

A plurality of second cell active regions AC may be defined in the substrate 100 by first element isolation patterns 412A and second element isolation patterns 414A. The channel structures 430A may be arranged in the respective second cell active regions AC. The channel structures 430A may each include first and second active pillars 430A1 and 430A2 extending in a vertical direction, and a connection portion 430L connecting the bottom portions of the first and second active pillars 430A1 and 430A2. Third source/drain regions SD1 may be arranged in the connection portions 430L of the channel structures 430A. Fourth source/drain regions SD2 may be arranged on the upper sides of the first active pillars 430A1 of the channel structures 430A and the upper sides of the second active pillars 430A2 of the channel structures 430A. The first active pillars 430A1 and the second active pillars 430A2 may form independent unit memory cells.

The first conductive lines 420A may extend in a direction intersecting the second cell active regions AC, for example, in a second direction D2. One first conductive line 420A may be arranged on the connection portion 430L between first and second active pillars 430A1 and 430A2, and may be positioned on a third source/drain region SD1, and another adjacent first conductive line 420A may be arranged between two channel structures 430A. Each first conductive lines 420A may function as a common bitline, including two unit memory cells formed by first and second active pillars 430A1 and 430A2 positioned on either side.

Each contact gate electrode 440A may be arranged between two adjacent channel structures 430A in the second direction D2. For example, each contact gate electrode 440A may be positioned between the first active pillar 430A1 of one channel structure 430A and the second active pillar 430A2 of an adjacent channel structure 430A. Each contact gate electrode 440A may be shared by the first and second active pillars 430A1 and 430A2 arranged on its both sidewalls. Fourth gate insulating films 450A may be positioned between the contact gate electrodes 440A and the first active pillars 430A1 and between the contact gate electrodes 440A and the second active pillars 430A2. A plurality of second conductive lines 442A may extend in the first direction D1 on the top surfaces of the contact gate electrodes 440A. The second conductive lines 442A may function as wordlines.

Capacitor contacts 460A may be arranged on the channel structures 430A. The capacitor contacts 460A may be positioned on the fourth source/drain regions SD2, and the second capacitor 480 may be positioned on the capacitor contacts 460A.

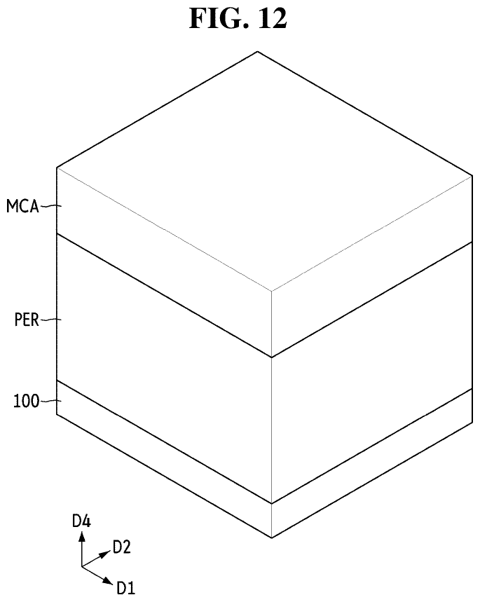

FIG. 12 is a diagram illustrating a semiconductor device according to some embodiments.

Referring to FIG. 12, the semiconductor device according to some embodiments may include a peripheral gate structure PER and a memory cell structure MCA.

The peripheral gate structure PER and the memory cell structure MCA may be arranged on a substrate 100. For example, the peripheral gate structure PER may be arranged between the substrate 100 and the memory cell structure MCA.

For example, the semiconductor device described with reference to FIGS. 1 and 2 may be arranged in the peripheral gate structure PER, and the semiconductor device described with reference to FIGS. 3 through 11 may be arranged in the memory cell structure MCA. In other words, the first and second capacitors 390 and 480 and the bitlines included in the memory cell structure MCA may be arranged on the first and second gate electrode layers 120A and 220A (in FIG. 1) included in the peripheral gate structure PER.

Unlike what is illustrated, the memory cell structure MCA may be arranged between the peripheral gate structure PER and the substrate 100.

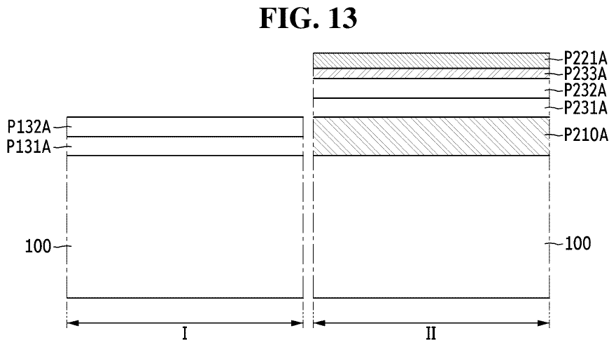

FIGS. 13 through 17 are intermediate-step diagrams illustrating a method for fabricating a semiconductor device according to some embodiments. For convenience, overlapping descriptions with those provided using FIGS. 1 through 12 will be briefly summarized or omitted.

Referring to FIG. 13, a pre-silicon germanium film P210A is formed on a second region II of a substrate 100. Thereafter, a first pre-interface film P131A and a second pre-interface film P231A are formed on a first region I and the second region II of the substrate 100, and a first pre-high-k insulating film P132A and a second pre-high-k insulating film P232A are formed. Thereafter, a second pre-conductivity-type metal oxide film P233A and a second pre-electrode film P221A are sequentially formed on the second region II of the substrate 100.

The first pre-interface film P131A and the first pre-high-k insulating film P132A may correspond to the first interface film 131A and the first high-k insulating film 132A, respectively, of FIG. 1. The second pre-interface film P231A and the second pre-high-k insulating film P232A may correspond to the second interface film 231A and the second high-k insulating film 232A, respectively, of FIG. 1.

The first pre-interface film P131A and the second pre-interface film P231A may each include, for example, a silicon oxide film. The first pre-high-k insulating film P132A and the second pre-high-k insulating film P232A may each include, for example, a high-k material having a higher dielectric constant than silicon oxide, such as hafnium oxide.

The second pre-conductivity-type metal oxide film P233A and the second pre-electrode film P221A may correspond to the second conductive metal oxide film 233A and the second electrode film 221A, respectively, of FIG. 1. The second pre-conductivity-type metal oxide film P233A may include, for example, an oxide of a p-type dipole element, such as aluminum. The second pre-electrode film P221A may include, for example, at least one of TiN, TiAlC, and TiAlN.

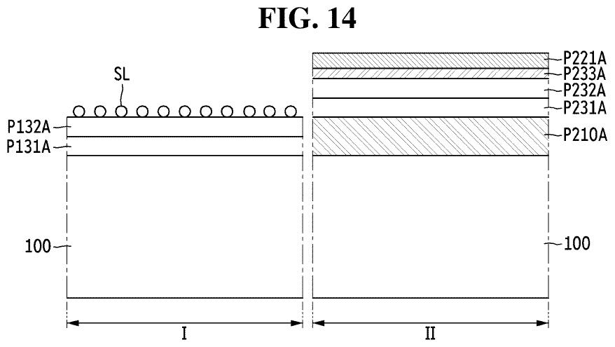

Referring to FIG. 14, a sacrificial material SL is selectively formed on the first region I of the substrate 100. The sacrificial material SL may be formed only on the first region I of the substrate 100 and may not be formed on the second region II. The sacrificial material SL is formed on the first pre-high-k insulating film P132A. The sacrificial material SL may include, for example, at least one of aniline, toluene, benzene, cyclohexane, or pyrimidine. For example, the sacrificial material SL may be formed in situ within a semiconductor fabrication facility but is not limited thereto.

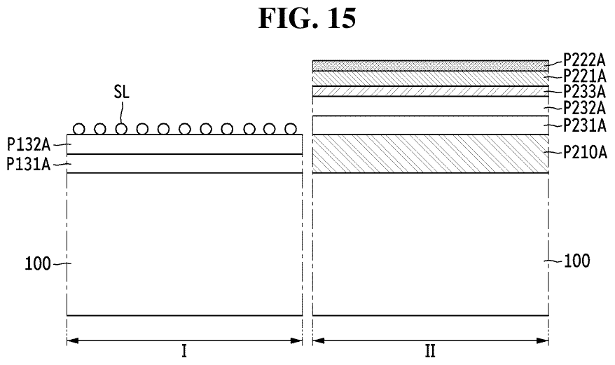

Referring to FIG. 15, a pre-barrier film P222A is selectively formed on the second region II of the substrate 100. The pre-barrier film P222A may be formed only on the second region II of the substrate 100 and may not be formed on the first region I. The pre-barrier film P222A is formed on the second pre-electrode film P221A but may not be formed on the first pre-high-k insulating film P132A. The pre-barrier film P222A may correspond to the barrier film 222A of FIG. 1. The pre-barrier film P222A may include a semimetal material. For example, the pre-barrier film P222A may include at least one of PtSe₂, PdSe₂, or TiS₂. The pre-barrier film P222A may be formed on the second pre-electrode film P221A via area-selective atomic layer deposition (ALD).

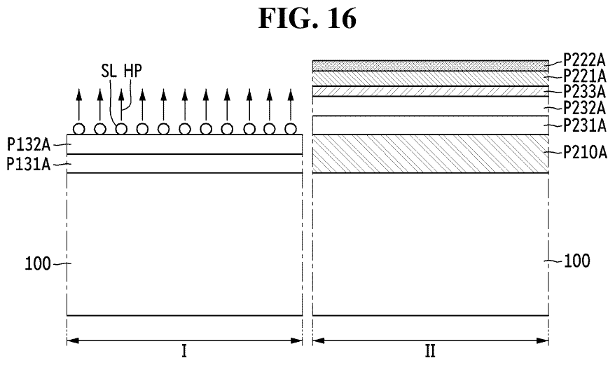

Referring to FIG. 16, the sacrificial material SL selectively formed on the first region I of the substrate 100 is removed through a heat treatment process HP. For example, the sacrificial material SL may be removed through plasma treatment in an argon and/or hydrogen atmosphere.

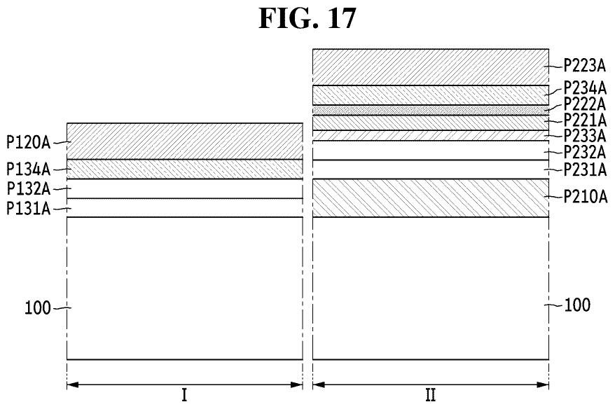

Referring to FIG. 17, after the sacrificial material SL is removed, a (1_1)-th pre-conductivity-type metal oxide film P134A and a (1_2)-th pre-conductivity-type metal oxide film P234A are formed on the first pre-high-k insulating film P132A and the pre-barrier film P222A, respectively, and a first pre-gate electrode layer P120A and a (1_2)-th pre-electrode film P223A are formed.

The (1_1)-th pre-conductivity-type metal oxide film P134A and the first pre-gate electrode layer P120A may correspond to the (1_1)-th conductive metal oxide film 134A and the first gate electrode layer 120A of FIG. 1, respectively. The (1_1)-th pre-conductivity-type metal oxide film P134A may include an oxide of an n-type dipole element, such as lanthanum. The first pre-gate electrode layer P120A may include, for example, at least one of TiN, TiAlC, or TiAlN.

The (1_2)-th pre-conductivity-type metal oxide film P234A and the (1_2)-th pre-electrode film P223A may correspond to the (1_2)-th conductive metal oxide film 234A and the (1_2)-th electrode film 223A, respectively, of FIG. 1. The (1_2)-th pre-conductivity-type metal oxide film P234A may include an oxide of an n-type dipole element, such as lanthanum. The (1_2)-th pre-electrode film P223A may include, for example, at least one of TiN, TiAlC, or TiAlN.

Through this process, a first gate structure GS1A, including the first gate electrode layer 120A and the first gate insulating layer 130A of FIG. 1, and a second gate structure GS2A, including the second gate electrode layer 220A and the second gate insulating layer 230A of FIG. 1, may be formed.

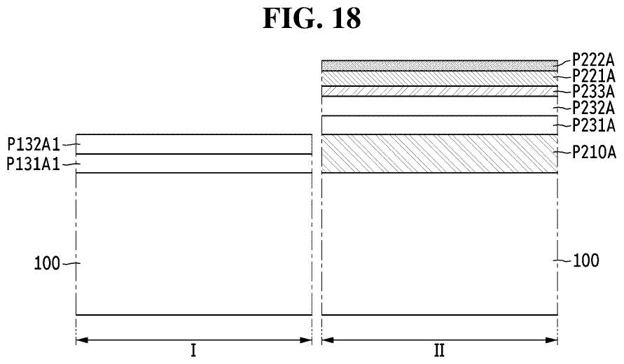

FIG. 18 is an intermediate-step diagram illustrating a method for fabricating a semiconductor device according to some embodiments. For convenience, overlapping descriptions with those provided using FIGS. 1 through 17 will be briefly summarized or omitted. For reference, FIG. 18 may be a diagram illustrating a manufacturing process subsequent to the step illustrated in FIG. 13.

Referring to FIG. 18, a pre-silicon germanium film P210A is formed on a second region II of a substrate 100. Thereafter, a first pre-interface film P131A and a second pre-interface film P231A are formed on a first region I and the second region II of the substrate 100, and then a first pre-high-k insulating film P132A1 and a second pre-high-k insulating film P232A are formed. Thereafter, a second pre-conductivity-type metal oxide film P233A and a second pre-electrode film P221A are sequentially formed on the first and second regions I and II of the substrate 100. A pre-barrier film P222A is subsequently formed on both the first and second regions I and II of the substrate 100.

The first and second pre-interface films P131A and P231A may each include, for example, a silicon oxide film. The first and second pre-high-k insulating films P132A1 and P232A may each include, for example, a high-k material having a higher dielectric constant than silicon oxide, such as hafnium oxide.

The second pre-conductivity-type metal oxide film P233A may include, for example, an oxide of a p-type dipole element, such as aluminum. The second pre-electrode film P221A may include, for example, at least one of TiN, TiAlC, or TiAlN.

The pre-barrier film P222A may include a semimetal material. For example, the pre-barrier film P222A may include at least one of PtSe₂, PdSe₂, or TiS₂.

Thereafter, the second pre-conductivity-type metal oxide film P233A, the second pre-electrode film P221A, and the pre-barrier film P222A on the first region I of the substrate 100 are selectively removed. As a result, the pre-barrier film P222A may be selectively formed on the second region II of the substrate 100.

Through this process, a first gate structure GS1A, including the first gate electrode layer 120A and the first gate insulating layer 130A of FIG. 1, and a second gate structure GS2A, including the second gate electrode layer 220A and the second gate insulating layer 230A of FIG. 1, may be formed.

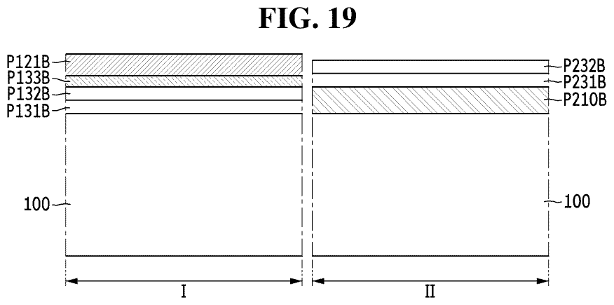

FIGS. 19 through 23 are intermediate-step diagrams illustrating a method for fabricating a semiconductor device according to some embodiments. For convenience, overlapping descriptions with those provided using FIGS. 1 through 18 will be briefly summarized or omitted.

Referring to FIG. 19, a pre-silicon germanium film P210B is formed on the second region II of a substrate 100. Thereafter, a first pre-interface film P131B and a second pre-interface film P231B are formed on the first and second regions I and II of the substrate 100, and then a first pre-high-k insulating film P132B and a second pre-high-k insulating film P232B are formed. Thereafter, a first pre-conductivity-type metal oxide film P133B and a second pre-electrode film P121B are selectively formed on the first region I of the substrate 100.

The first pre-interface film P131B and the first pre-high-k insulating film P132B may correspond to the first interface film 131B and the first high-k insulating film 132B, respectively, of FIG. 2. The second pre-interface film P231B and the second pre-high-k insulating film P232B may correspond to the second interface film 231B and the second high-k insulating film 232B, respectively, of FIG. 2.

The first and second pre-interface films P131B and P231B may each include, for example, a silicon oxide film. The first and second pre-interface films P131B and P231B may include, for example, a high-k material having a higher dielectric constant than silicon oxide, such as hafnium oxide.

The first pre-conductivity-type metal oxide film P133B and the second pre-electrode film P121B may correspond to the first conductive metal oxide film 133B and the second electrode film 121B, respectively, of FIG. 2. The first pre-conductivity-type metal oxide film P133B may include, for example, an oxide of an n-type dipole element, such as lanthanum. The second pre-electrode film P121B may include, for example, at least one of TiN, TiAlC, or TiAlN.

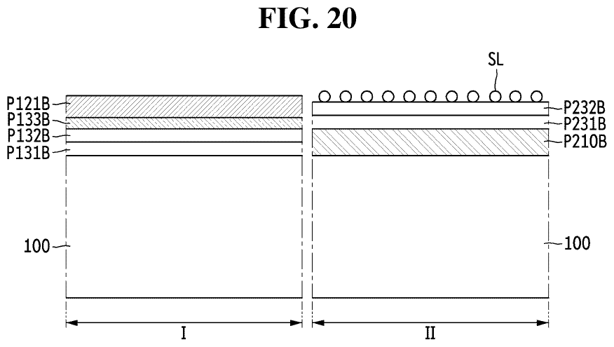

Referring to FIG. 20, a sacrificial material SL is selectively formed on the second region II of the substrate 100. The sacrificial material SL may be formed only on the second region II of the substrate 100 and may not be formed on the first region I. The sacrificial material SL is formed on the second pre-high-k insulating film P232B. The sacrificial material SL may include, for example, at least one of aniline, toluene, benzene, cyclohexane, or pyrimidine. For example, the sacrificial material SL may be formed in situ within a semiconductor fabrication facility, but is not limited thereto.

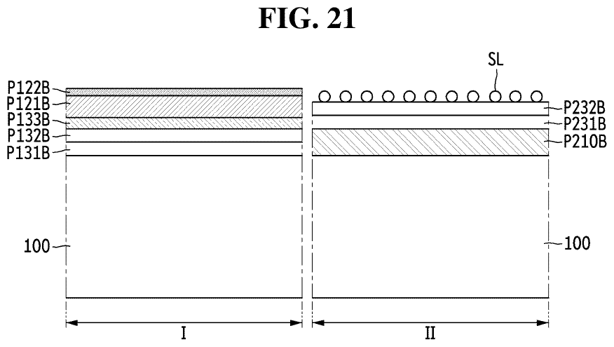

Referring to FIG. 21, a pre-barrier film P122B is selectively formed on the first region I of the substrate 100. The pre-barrier film P122B may be formed only on the first region I of the substrate 100 and may not be formed on the second region II. The pre-barrier film P122B is formed on the second pre-electrode film P121B but may not be formed on the second pre-high-k insulating film P232B. The pre-barrier film P122B may correspond to the barrier film 122B of FIG. 2. The pre-barrier film P122B may include a semimetal material. For example, the pre-barrier film P122B may include at least one of PtSe₂, PdSe₂, or TiS₂. The pre-barrier film P122B may be formed on the second pre-electrode film P121B via area-selective ALD.

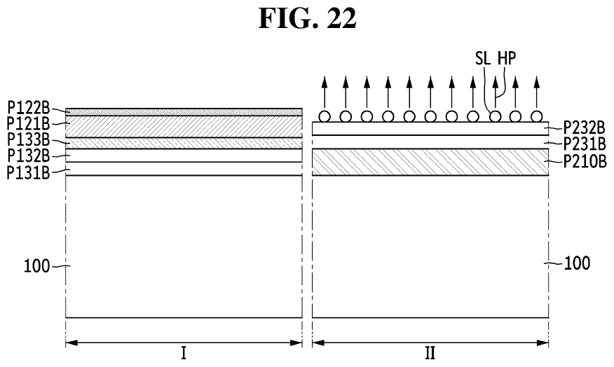

Referring to FIG. 22, the sacrificial material SL selectively formed on the second region II of the substrate 100 is removed through a heat treatment process HP. For example, the sacrificial material SL may be removed through plasma treatment in an argon and/or hydrogen atmosphere.

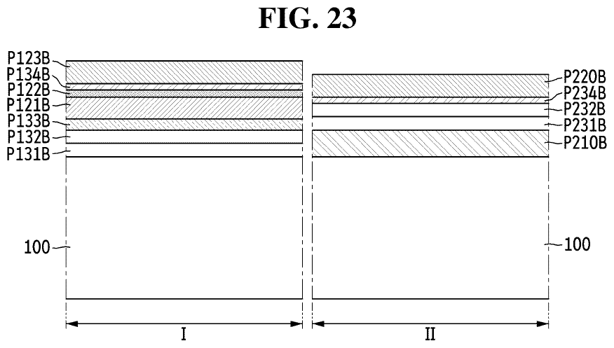

Referring to FIG. 23, after the removal of the sacrificial material SL, a (2_2)-th pre-conductivity-type metal oxide film P234B and a (2_1)-th pre-conductivity-type metal oxide film P134B are formed on the second pre-high-k insulating film P232B and the pre-barrier film P122B, respectively, and a second pre-gate electrode layer P220B and a (2_2)-th pre-electrode film P123B are formed.

The (2_2)-th pre-conductivity-type metal oxide film P234B and the second pre-gate electrode layer P220B may correspond to the (2_2)-th conductive metal oxide film 234B and the second gate electrode layer 220B, respectively, of FIG. 2. The (2_2)-th pre-conductivity-type metal oxide film P234B may include an oxide of a p-type dipole element, such as aluminum. The second pre-gate electrode layer P220B may include, for example, at least one of TiN, TiAlC, and TiAlN.

The (2_1)-th pre-conductivity-type metal oxide film P134B and the (2_2)-th pre-electrode film P123B may correspond to the (2_1)-th conductive metal oxide film 134B and the (1_2)-th electrode film 123B, respectively, of FIG. 2. The (2_1)-th pre-conductivity-type metal oxide film P134B may include an oxide of a p-type dipole element, such as aluminum. The (2_2)-th pre-electrode film P123B may include, for example, at least one of TiN, TiAlC, or TiAlN.

Through this process, a first gate structure GS1B, including the first gate electrode layer 120B and the first gate insulating layer 130B of FIG. 2, and a second gate structure GS2B, including the second gate electrode layer 220B and the second gate insulating layer 230B of FIG. 2, may be formed.

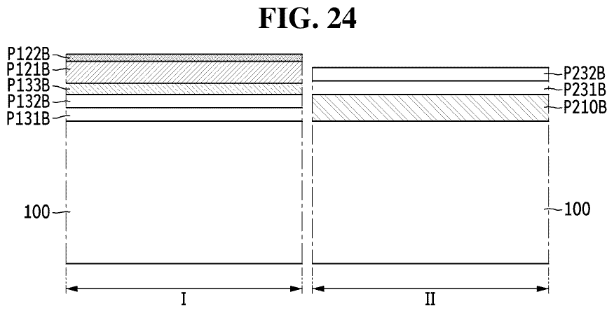

FIG. 24 is an intermediate-step diagram illustrating a method for fabricating a semiconductor device according to some embodiments. For convenience, overlapping descriptions with those provided using FIGS. 1 through 23 will be briefly summarized or omitted. For reference, FIG. 24 may be a diagram illustrating a manufacturing process subsequent to the step illustrated in FIG. 19.

Referring to FIG. 24, a pre-silicon germanium film P210B is formed on the second region II of the substrate 100. Thereafter, a first pre-interface film P131B and a second pre-interface film P231B are formed on the first region I and the second region II of the substrate 100, and then a first pre-high-k insulating film P132B and a second pre-high-k insulating film P232B are formed. Thereafter, a first pre-conductivity-type metal oxide film P133B and a second pre-electrode film P121B are sequentially formed on the first region I and the second region II of the substrate 100. A pre-barrier film P122B is then formed on the first region I and the second region II of the substrate 100.

The first and second pre-interface films P131B and P231B may each include, for example, a silicon oxide film. The first and second pre-high-k insulating films P132B and P232B may include, for example, a high-k material having a higher dielectric constant than silicon oxide, such as hafnium oxide.

The first pre-conductivity-type metal oxide film P133B may include, for example, an oxide of an n-type dipole element, such as lanthanum. The second pre-electrode film P121B may include, for example, at least one of TiN, TiAlC, or TiAlN.

The pre-barrier film P122B may include a semimetal material. For example, the pre-barrier film P122B may include at least one of PtSe₂, PdSe₂, or TiS₂.

Thereafter, the first pre-conductivity-type metal oxide film P133B, the second pre-electrode film P121B, and the pre-barrier film P122B on the second region II of the substrate 100 are selectively removed. As a result, the pre-barrier film P122B may be selectively formed on the first region I of the substrate 100.

Although the embodiments of the present disclosure have been described with reference to the accompanying drawings, the present disclosure is not limited to these embodiments and may be manufactured in various other forms. Those skilled in the art will understand that the technical scope or essential characteristics of the present disclosure can be modified and implemented in other specific forms without departing from the spirit of the invention. Therefore, the embodiments described above should be understood as being illustrative in all respects and not limiting.

What is claimed is:

1. A semiconductor device comprising:
a substrate including a first region and a second region;
a first gate structure in the first region, including a first gate insulating layer that includes a first high-k film and a first conductivity-type metal oxide film of a first conductivity type, and a first gate electrode layer on the first gate insulating layer; and
a second gate structure in the second region, including a second gate insulating layer that includes a second high-k film, the first conductivity-type metal oxide film, and a second conductivity-type metal oxide film of a second conductivity-type different from the first conductivity type, and a second gate electrode layer on the second gate insulating layer,
wherein:
the second gate electrode layer includes a barrier film between the first conductivity-type metal oxide film and the second high-k film, and
the barrier film includes a semimetal material.

2. The semiconductor device of claim 1, wherein
the barrier film is positioned between the second conductivity-type metal oxide film and the first conductivity-type metal oxide film, and
the second conductivity-type metal oxide film is positioned between the second high-k film and the first conductivity-type metal oxide film.

3. The semiconductor device of claim 1, wherein
the second gate electrode layer further includes a first electrode film on the first conductivity-type metal oxide film and a second electrode film on the second conductivity-type metal oxide film, and
the barrier film is positioned between the first electrode film and the second electrode film.

4. The semiconductor device of claim 3, wherein
the barrier film is positioned between the second electrode film and the first conductivity-type metal oxide film, and
the second conductivity-type metal oxide film is positioned between the second high-k film and the second electrode film.

5. The semiconductor device of claim 1, wherein
the first gate insulating layer further includes a first interface film between the substrate and the first high-k film, and
the second gate insulating layer further includes a second interface film between the substrate and the second high-k film.

6. The semiconductor device of claim 5, wherein the first gate insulating layer includes a metal material included in the first conductivity-type metal oxide film between the first interface film and the first high-k film.

7. The semiconductor device of claim 5, wherein the second gate insulating layer does not include a metal material included in the first conductivity-type metal oxide film between the second interface film and the second high-k film.

8. The semiconductor device of claim 1, wherein the first gate electrode layer does not include the barrier film.

9. The semiconductor device of claim 1, wherein:
the first conductivity-type metal oxide film includes lanthanum (La), and
the second conductivity-type metal oxide film includes aluminum (Al).

10. The semiconductor device of claim 1, wherein:
the first conductivity-type metal oxide film includes Al, and
the second conductivity-type metal oxide film includes La.

11. The semiconductor device of claim 1, wherein each of the first and second gate electrode layers includes at least one of TiN, TiAlC, or TiAlN.

12. A semiconductor device comprising:
a substrate including a first region and a second region;
a first transistor in the first region, including a first gate insulating layer and a first gate electrode layer; and
a second transistor in the second region, including a second gate insulating layer and a second gate electrode layer,
wherein:
the first gate insulating layer includes a first high-k film on the substrate and a first metal oxide film including a first conductivity-type metal material,
the second gate insulating layer includes a second high-k film on the substrate, the first metal oxide film, and a second metal oxide film including a second conductivity-type metal material different from the first conductivity-type metal material,
the second gate electrode layer includes a barrier film between the first metal oxide film and the second high-k film, and
the second high-k film does not include the first conductivity-type metal material.

13. The semiconductor device of claim 12, wherein the first high-k film includes the first conductivity-type metal material.

14. The semiconductor device of claim 12, wherein the first gate electrode layer does not include the barrier film.

15. The semiconductor device of claim 12, wherein the second transistor further includes a silicon germanium layer between the substrate and the second gate insulating layer.

16. The semiconductor device of claim 12, wherein:
the first transistor is an N-type metal-oxide semiconductor (NMOS) transistor, and
the second transistor is a P-type metal-oxide semiconductor (PMOS) transistor.

17. The semiconductor device of claim 12, wherein:
the first transistor is a PMOS transistor, and
the second transistor is an NMOS transistor.

18. A semiconductor device comprising:
a substrate including a cell array region, a first peripheral region, and a second peripheral region;
a cell structure in the cell array region, including bitlines extending in a first direction, wordlines extending in a second direction that intersects the first direction, and a capacitor on the bitlines;
a first transistor in the first peripheral region, including a first gate insulating layer that includes a first high-k film and a first conductivity-type metal oxide film of a first conductivity type, and a first gate electrode layer on the first gate insulating layer; and
a second transistor in the second peripheral region, including a second gate insulating layer that includes a second high-k film, the first conductivity-type metal oxide film, and a second conductivity-type metal oxide film of a second conductivity type different from the first conductivity type, and a second gate electrode layer on the second gate insulating layer,
wherein:
the second gate electrode layer includes a barrier film between the first conductivity-type metal oxide film and the second high-k film, and
the barrier film includes a semimetal material.

19. The semiconductor device of claim 18, wherein:
the first high-k film includes the first conductivity-type metal material, and
the second high-k film does not include the first conductivity-type metal material.

20. The semiconductor device of claim 18, wherein:
the first gate electrode layer includes a first electrode film,
the second gate electrode layer includes the first electrode film and a second electrode film, and
a thickness of the first electrode film is different than a thickness of the second electrode film.
